(19) United States
(12) Patent Application Publication
(10) Pub. No.: US 2006/0102827 A1
(43) Pub. Date: May 18, 2006

(54) Solid-state imaging device

(75) Inventors: Shigetaka Kasuga, Hirakata-shi (JP); Takumi Yamaguchi, Kyoto-shi (JP); Takahiko Murata, Osaka-shi (JP)

Correspondence Address: GREENBLUM & BERNSTEIN, P.L.C., 1950 ROLAND CLARKE PLACE, RESTON, VA, 20191, US

(73) Assignee: Matsushita Electric Industrial Co., Ltd., Osaka (JP)

(21) Appl. No.: 11/272,895

(22) Filed: Nov. 15, 2005

(30) Foreign Application Priority Data
Nov. 17, 2004 (JP) 2004-333208
Feb. 4, 2005 (JP) 2005-029734

(51) Int. Cl. H01L 27/00

(52) U.S. Cl. 250/208.1

(57) ABSTRACT

Provided is a solid-state imaging device which can obtain an output characteristic without preventing linearity even in a high light-intensity range, and at the same time achieve a much wider dynamic range. The solid-state imaging device 1 includes: a photo-detecting element (a photoelectric transducer PD) for transducing incident light to electric charges and accumulate the electric charges; an accumulation element (a floating de-fusion FD) for accumulating the electric charges; and a transfer circuit (a MOS transistor Q11 and a pulse generating circuit 50a) for transferring the electric charges accumulated in the photo-detecting element to the accumulation element, wherein the transfer circuit has two operation modes as follows: a whole transfer for transferring almost all of the accumulated electric charges to the accumulation element; and a partial transfer for transferring only a part of the accumulated electric charges which exceeds a predetermined amount to the accumulation element.

### BACKGROUND OF THE INVENTION

(1) Field of the Invention

The present invention relates to a Metal-Oxide-Semiconductor (MOS) solid-state imaging device which is used in a digital camera and the like, and more specifically to a technology to increase a dynamic range.

(2) Description of the Related Art

In recent years, as image colorization has progressed, a MOS solid-state imaging device has been significantly developed to be used for a digital still camera, a portable telephone having a camera function, and the like, and requirements for size minimization and pixel number increase of the solid-state imaging device have been increasing day by day. Such requirements for the solid-state imaging device, however, have reduced photo-detecting area of a photoelectric transducer which is a photo-detecting unit, and eventually have been contributing to reduce photoelectric transfer characteristics (photosensitivity and a dynamic range) which are main characteristics of the solid-state imaging device.

For example, an optical size of the solid-state imaging device built in a digital still camera is generally ⅓ to ¼ inch, and a ⅙ or smaller inch device has also being examined. Moreover, the number of pixels has been increasing from 2,000,000 pixels to 5,000,000 pixels, and a device with more than 5,000,000 pixels has also being examined. To achieve the photo-detecting area reduction and the pixel number increase, it has been getting necessary to establish a technology not to reduce the characteristics such as photosensitivity and dynamic range which are the main characteristics of the solid-state imaging device.

In other words, if only the pixel number increase is obtained without the pixel size reduction, this increases chip size and eventually increases the solid-state imaging device size, so that the pixel size reduction is necessary in parallel with the pixel number increase. In general, if the pixel size is reduced, a size of a photoelectric transducer such as a photodiode is also reduced, so that reduction in photosensitivity and a dynamic range caused by saturation when receiving high-intensity light is inevitable.

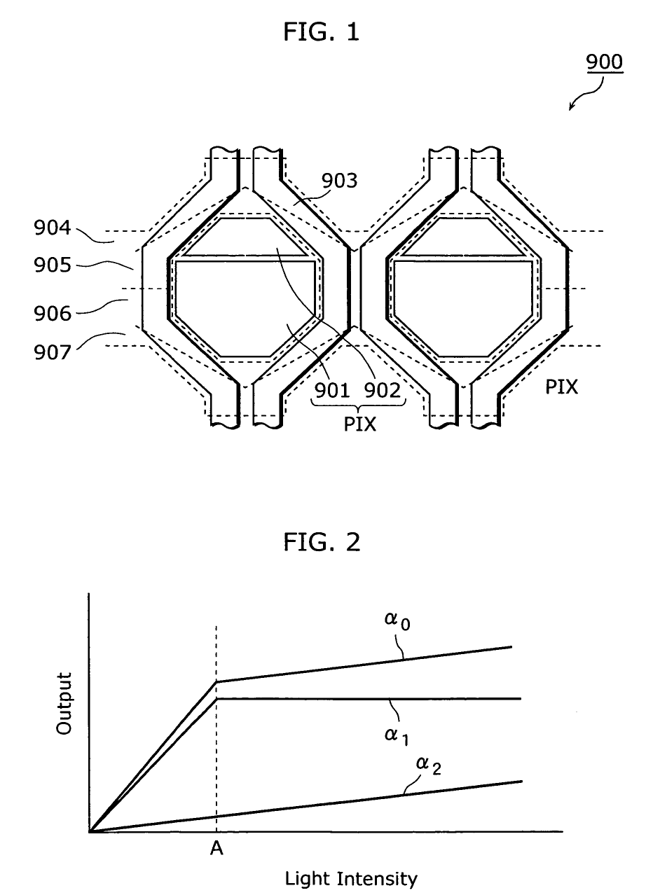

Therefore, a requirement for a wider dynamic range has been increasing, and as a conventional solid-state imaging device to achieve the wider dynamic range, one technology disclosed in Japanese Patent Laid-Open No. 2003-218343 publication is known. FIG. 1 shows a plan view of a common pixel unit in the conventional solid-state imaging device.

As shown in FIG. 1, a conventional solid-state imaging device 900 is comprised of: a main photo-detecting unit 901 having a relatively wide area formed in one pixel; a secondary photo-detecting unit 902 having a relatively narrow area formed in the same pixel; a charge transfer path 903 for transferring electric charges; and polysilicon electrodes 904, 905, 906, 907 for driving four stages.

FIG. 2 is a graph showing relationships between light intensity and output of the main photo-detecting unit 901 and the secondary photo-detecting unit 902. In FIG. 2, α1 represents a relationship between light intensity and output of the main photo-detecting unit 901 and it is seen that the light intensity is saturated at light intensity A and the output does not increase in a range where the light intensity is larger than the light intensity A. In FIG. 2, α2 represents a relationship between light intensity and output of the secondary photo-detecting unit 902 and it is seen that the light intensity is not saturated at light intensity A since the photosensitivity of the secondary photo-detecting unit 902 is lower than the photosensitivity of the main photo-detecting unit 901, and the output increases linearly even in the range where the light intensity is larger than the light intensity A. When the device is actually used, outputs of both of the main photo-detecting unit 901 and the secondary photo-detecting unit 902 are used, so that the output has characteristics as shown by α0 in FIG. 2.

However, in the conventional solid-state imaging device, the output α0 obtained by combining the output of the main photo-detecting unit 901 and the output of the secondary photo-detecting unit 902 of FIG. 1 shows that the linearity is damaged at the light intensity A and only a slightly wider dynamic range is achieved. Thereby, a dynamic range contrast in a highlighted range in one frame image is lowered.

### SUMMARY OF THE INVENTION

Accordingly, an object of the present invention is to provide a solid-state imaging device which can obtain an output characteristic without preventing linearity even in a high light intensity range, and at the same time achieve a much wider dynamic range.

To solve the above problem, a solid-state imaging device according to the present invention includes: a photo-detecting element operable to transduce incident light to electric charges and accumulate the electric charges; an accumulation element operable to accumulate the electric charges; and a transfer circuit operable to transfer the electric charges accumulated in the photo-detecting element to the accumulation element, wherein the transfer circuit has two operation modes of: a whole transfer for transferring almost all of the accumulated electric charges to the accumulation element; and a partial transfer for transferring only a part of the accumulated electric charges which exceeds a predetermined amount to the accumulation element.

Accordingly, without saturating the photo-detecting element, excessive electric charges are previously transferred to the accumulation element, so that it is possible to obtain the output characteristic without preventing linearity even in high light-intensity range and at the same time achieve the much wider dynamic range.

Furthermore, the transfer circuit may be operable to perform the partial transfer for a plurality of times and each interval between the partial transfers is different.

Accordingly, even if the incident light has high intensity, it is possible to obtain an optical response of a wide dynamic range proportional to the light intensity.

Furthermore, the partial transfer may be performed for three or more times and the intervals between the partial transfers become gradually shorter or longer.

Accordingly, even if the incident light has high intensity, it is possible to obtain an optical response of a wide dynamic range proportional to the light intensity.

Furthermore, the solid-state imaging device may further include a reset circuit operable to reset the accumulation element, wherein the reset circuit is operable to perform a reset operation before the whole transfer and before the partial transfer.

Accordingly, during one frame period, the reset operation is performed before the whole transfer and before the partial transfer in order to reset the accumulation element with a predetermined potential, so that it is possible to obtain an image without smears.

Furthermore, the solid-state imaging device may further include a reset circuit operable to reset the accumulation element, wherein the reset circuit is operable to perform a reset operation before the whole transfer and before each of the partial transfer which is performed for a plurality of times.

Accordingly, during one frame period, the reset operation is performed before the whole transfer and before the partial transfer in order to reset the accumulation element with a predetermined potential, so that it is possible to obtain an image without smears.

Furthermore, the accumulated electric charges transferred by the whole transfer may be added with the accumulated electric charges transferred by the partial transfer, only in a case where the accumulated electric charges transferred by the partial transfer exceed a predetermined amount.

Accordingly, by adding in the accumulation element the electric charges transferred by the whole transfer with the excessive electric charges transferred by the partial transfer, it is possible to output at once signals proportional to the electric charges accumulated in the accumulation element.

Furthermore, to solve the above problem, a solid-state imaging device according to the present invention includes a photo-detecting element operable to transduce incident light to electric charges and accumulate the electric charges; an accumulation element operable to accumulate the electric charges; a transfer circuit operable to transfer the electric charges accumulated in the photo-detecting element to the accumulation element; and a reset circuit operable to reset the accumulation element, wherein the reset circuit has two operation modes of: a whole reset for setting the accumulation element with an initial voltage; and a partial reset for setting the accumulation element with a predetermined voltage which is different from the initial voltage.

Accordingly, dark currents causing smears can be used effectively, and without saturating the photo-detecting element, it is possible to obtain the output characteristic without preventing linearity even in high light-intensity range and at the same time achieve the much wider dynamic range.

Furthermore, the reset circuit may be operable to perform for a plurality of times the partial resets each of which sets a different predetermined voltage.

Accordingly, it is possible to adjust the dark currents causing smears to be used effectively.

Furthermore, the partial reset may be performed for three or more times and the predetermined voltages become gradually lower or higher.

Accordingly, it is possible to adjust the dark currents causing smears to be used effectively.

Furthermore, the accumulated electric charges transferred after the whole reset may be added with the accumulated electric charges transferred after the partial transfer, only in a case where the accumulated electric charges transferred after the partial transfer exceed a predetermined amount.

Accordingly, by adding in the accumulation element the electric charges transferred by the whole transfer with the excessive electric charges transferred by the partial transfer, it is possible to output at once signals proportional to the electric charges accumulated in the accumulation element.

Furthermore, the transfer circuit may include an enhancement-mode transfer MOS transistor, and a threshold value of the transfer MOS transistor is set to be lower than threshold values of other enhancement-mode transfer MOS transistors included in the solid-state imaging device.

Accordingly, it is possible to easily control the whole transfer and the partial transfer, and the whole reset and the partial reset.

Furthermore, all transistors included in a circuit may be NMOS transistors, and a capacitor included in a circuit may be an NMOS capacitor.

Accordingly, it is possible to easily manufacture the solid-state imaging device.

As described above, in the solid-state imaging device according to the present invention, even if the incident light has high intensity, it is possible to obtain the output characteristic without preventing linearity even in high light-intensity range and at the same time achieve the much wider dynamic range.

Thus, the present invention can meet the requirement for a wider dynamic range and is highly suitable for practical use in these days when today when a digital camera and a portable telephone having a camera function have been widely used.

### FURTHER INFORMATION ABOUT TECHNICAL BACKGROUND TO THIS APPLICATION

The disclosures of Japanese Patent Applications Nos. 2004-333208 filed on Nov. 17, 2004 and 2005-29734 filed on Feb. 4, 20054 including specifications, drawings and claims are incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate specific embodiments of the present invention. In the

### DRAWINGS

FIG. 1 is a plan view showing a pixel unit in the conventional solid-state imaging device;

FIG. 2 is a graph showing relationships between light intensity and output of the main photo-detecting unit and the secondary photo-detecting unit in the conventional solid-state imaging device;

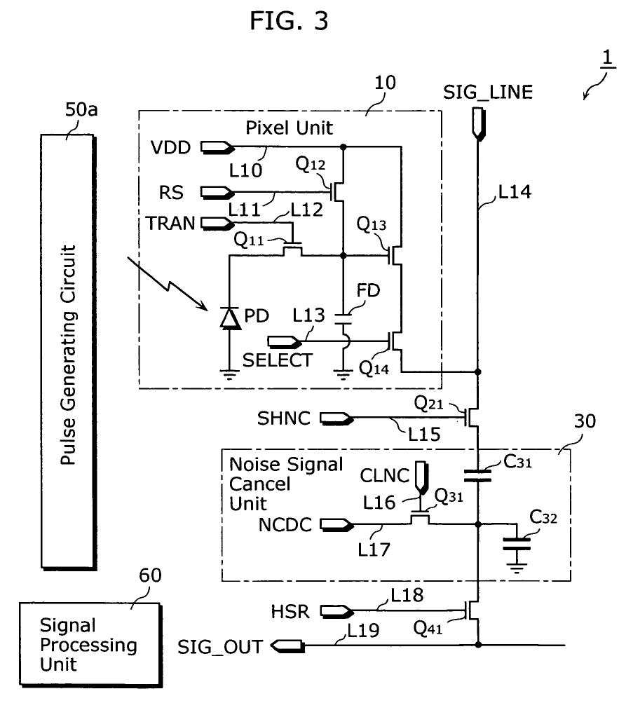

FIG. 3 is a circuit diagram showing a structure of a solid-state imaging device according to the first embodiment of the present invention;

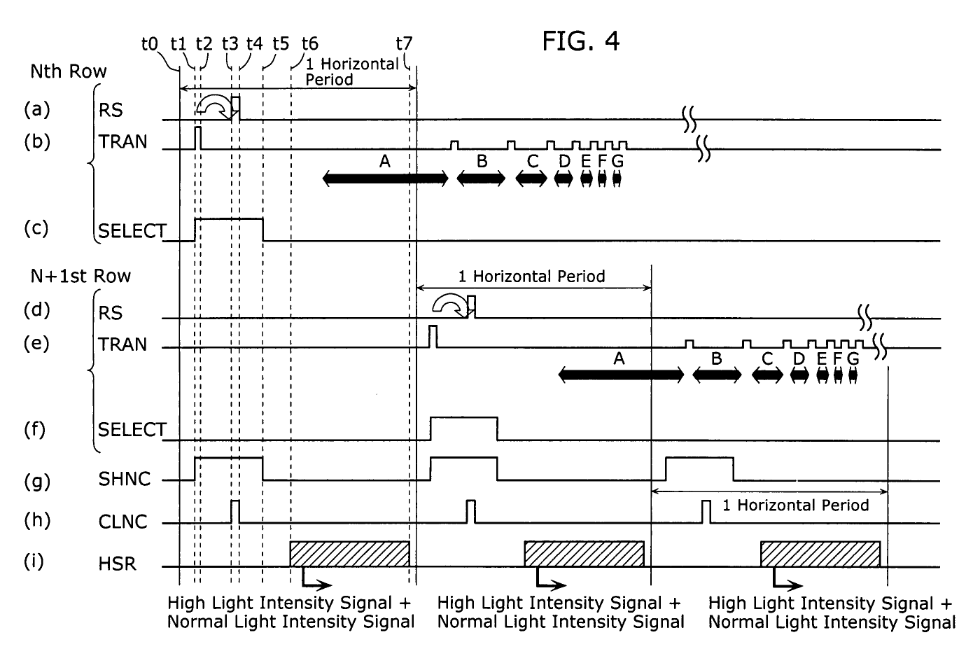

FIG. 4 is a time chart showing timings in operation of a solid-state imaging device 1 according to the first embodiment of the present invention;

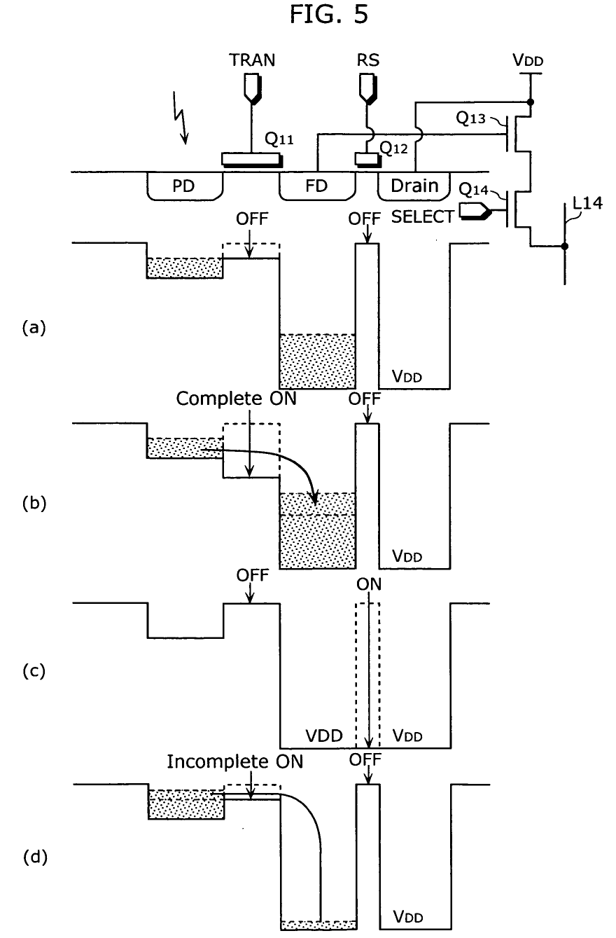

FIG. 5 is a diagram showing status of electric charges at main timings in FIG. 4;

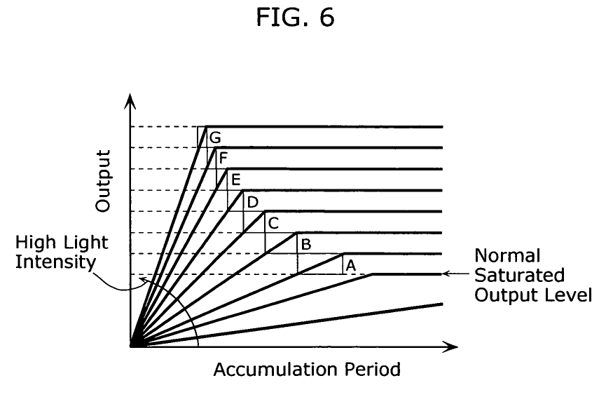

FIG. 6 is a graph showing relationships between accumulation time and output in the solid-state imaging device;

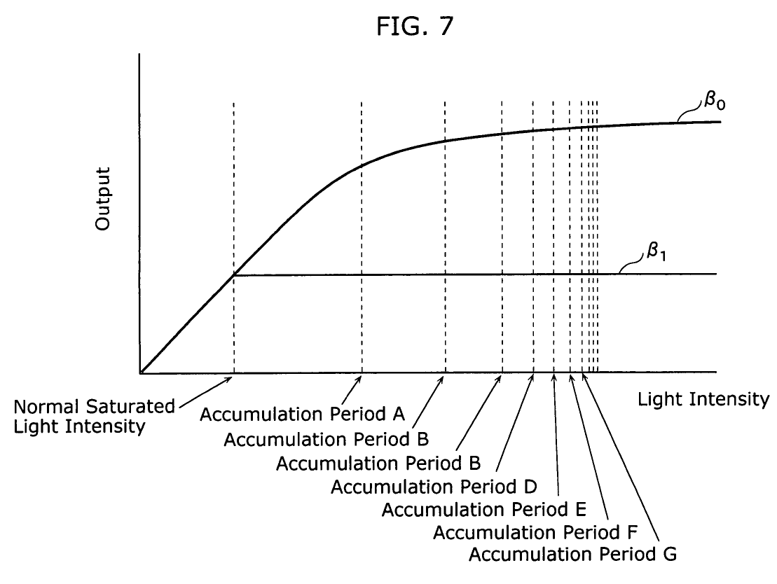

FIG. 7 is a graph showing relationships between light intensity and output in the solid-state imaging device;

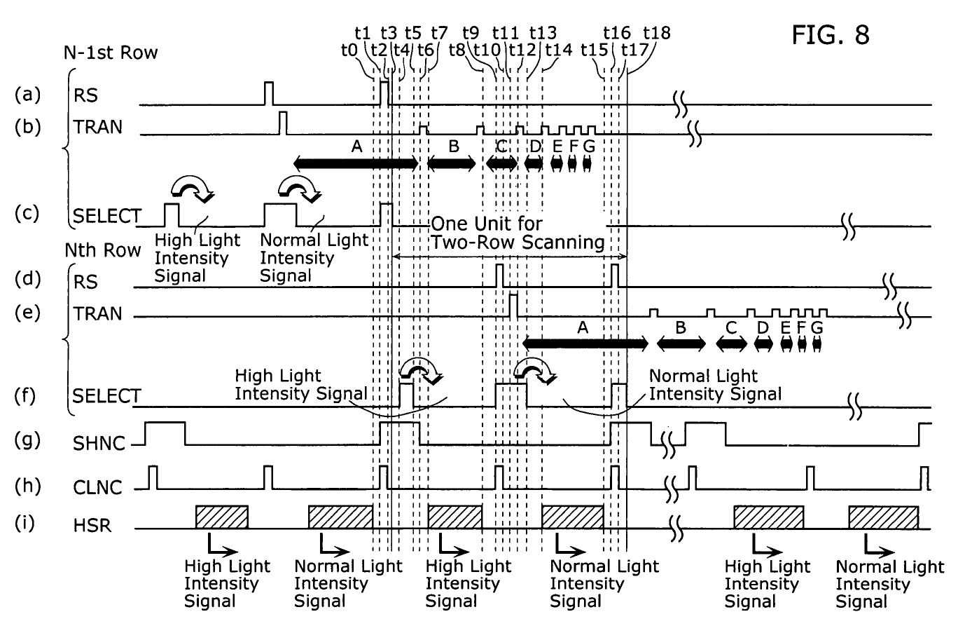

FIG. 8 is another time chart showing timings in operation of the solid-state imaging device 1 according to the second embodiment of the present invention;

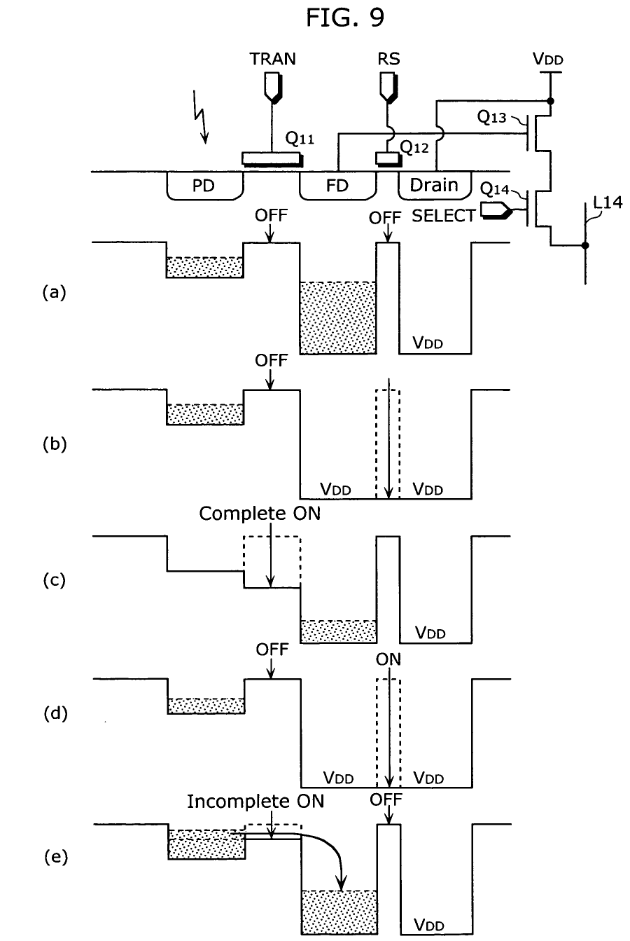

FIG. 9 is a diagram showing status of electric charges at main timings in FIG. 8;

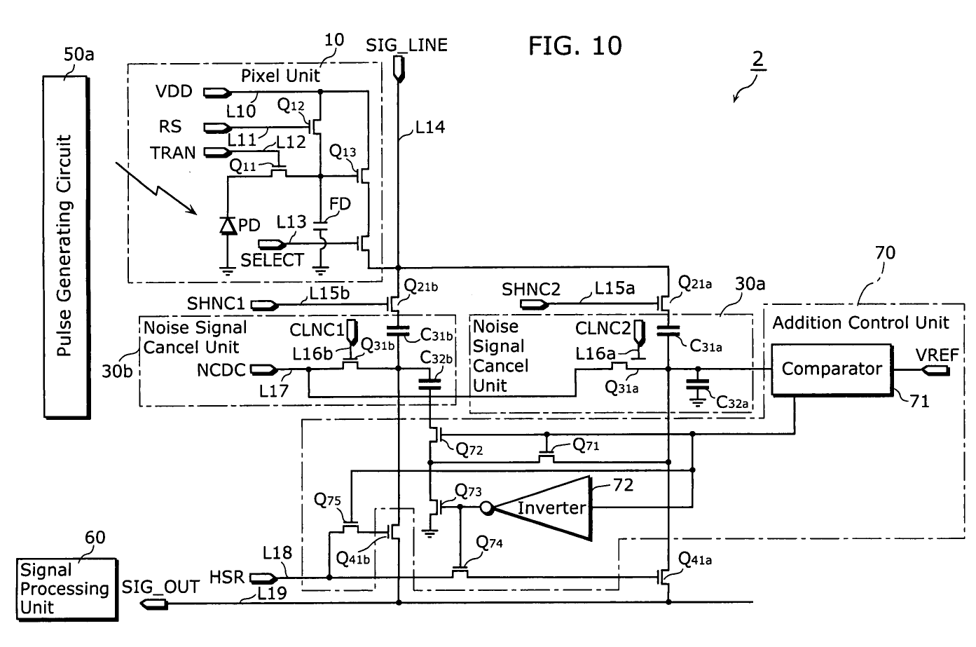

FIG. 10 is a circuit diagram showing a structure of a solid-state imaging device according to the third embodiment of the present invention;

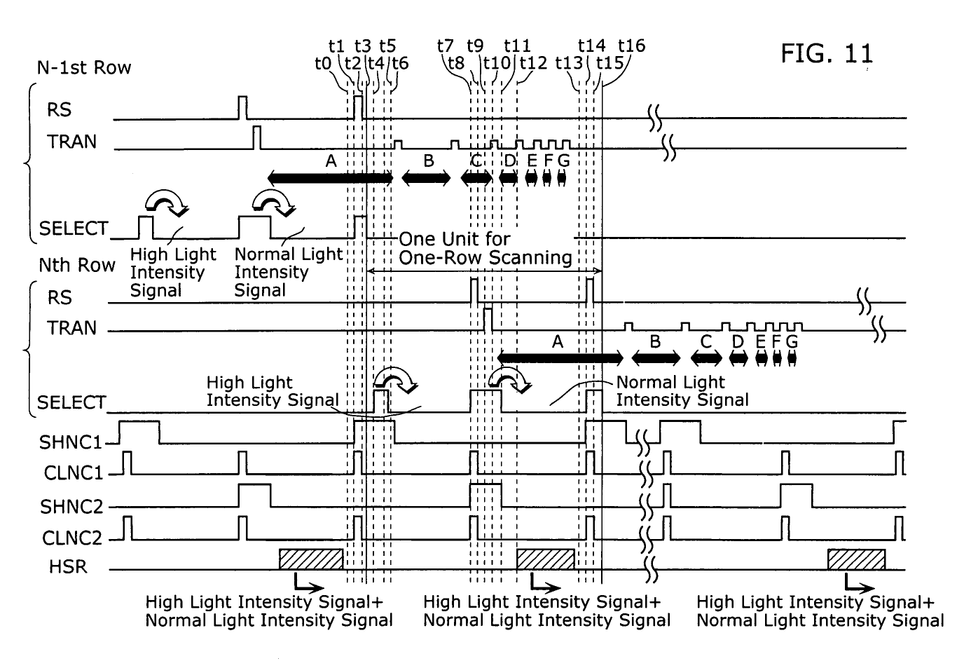

FIG. 11 is a time chart showing timings in operation of a solid-state imaging device 2 according to the third embodiment of the present invention;

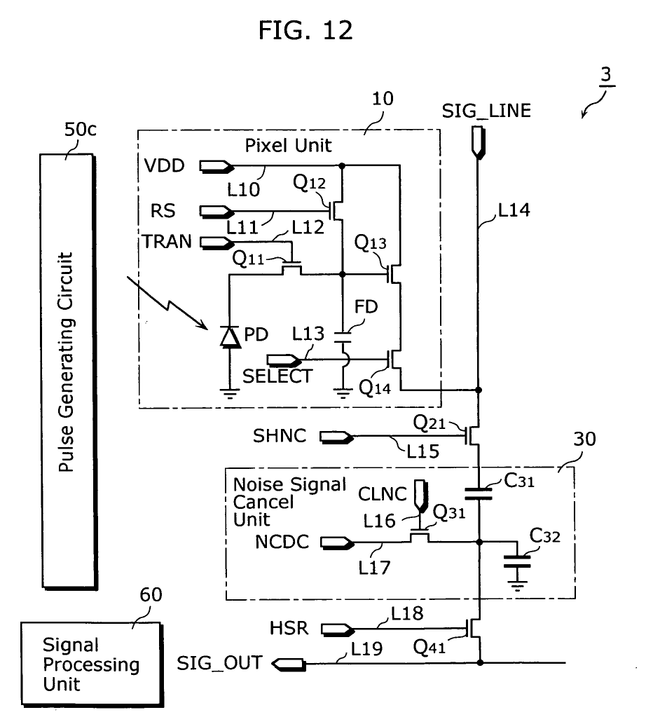

FIG. 12 is a circuit diagram showing a structure of a solid-state imaging device according to the fourth embodiment of the present invention;

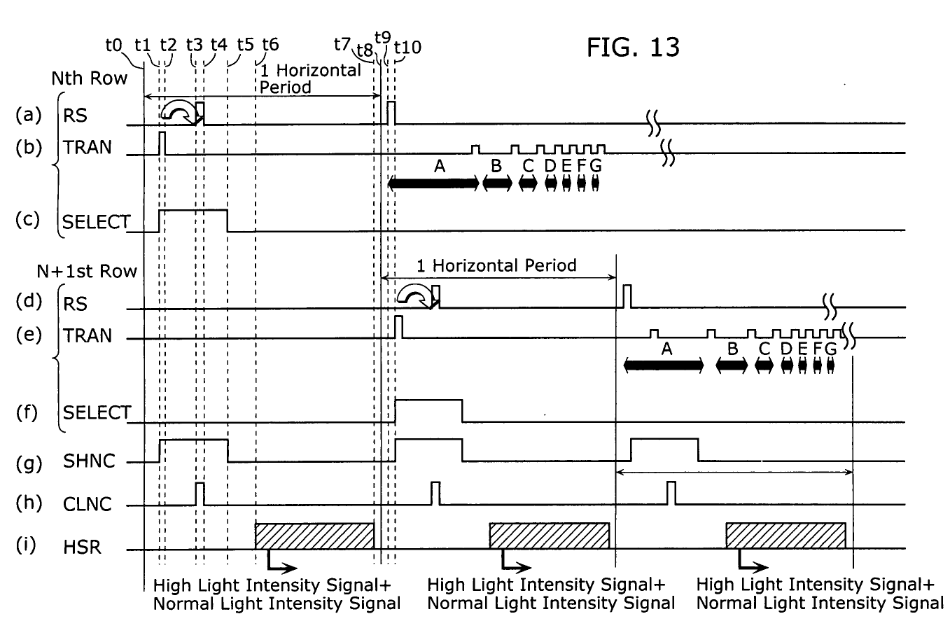

FIG. 13 is a time chart showing timings in operation of a solid-state imaging device 3 according to the fourth embodiment of the present invention;

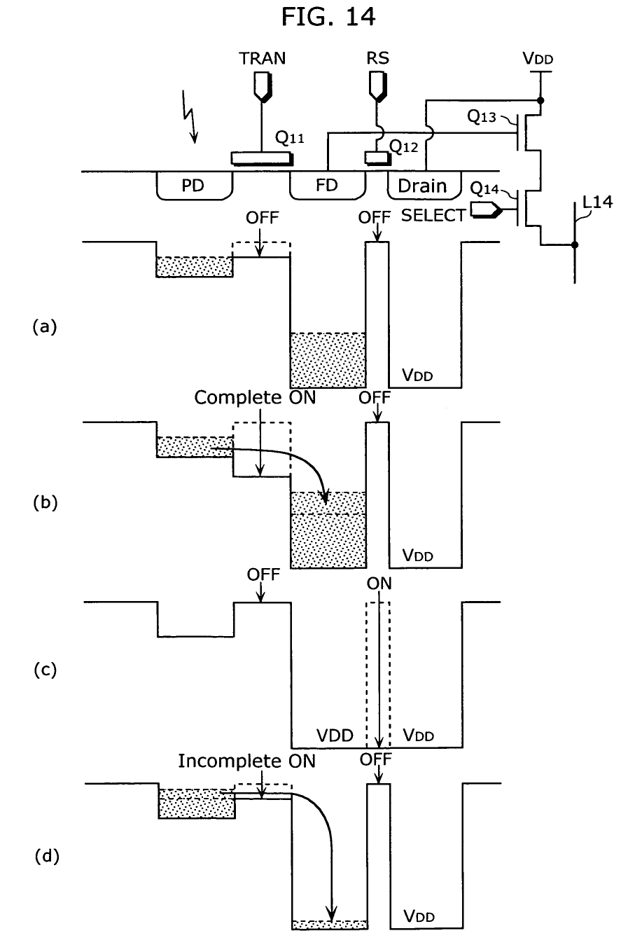

FIG. 14 is a diagram showing status of electric charges at main timings in FIG. 13;

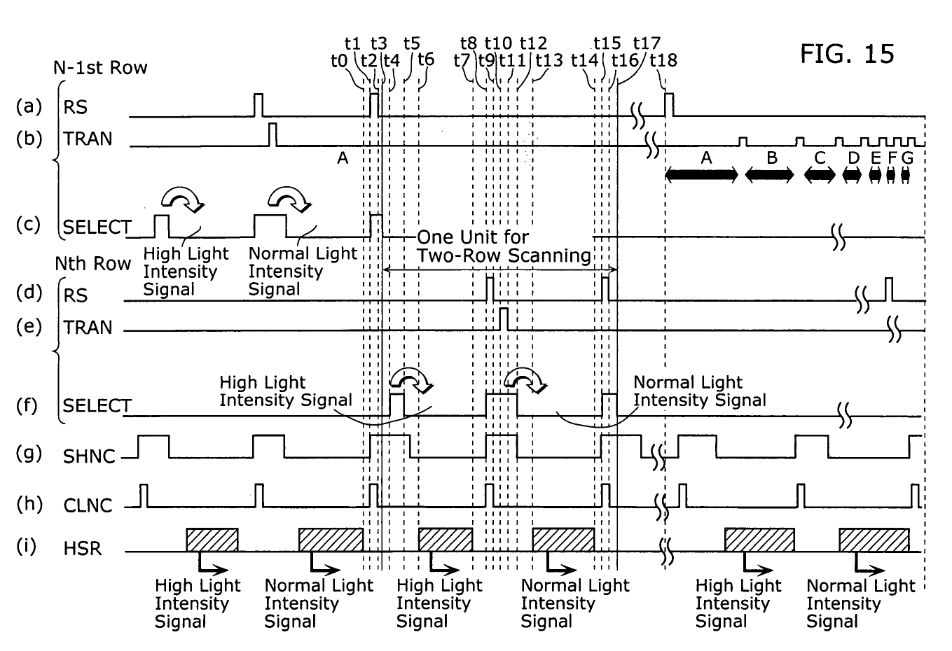

FIG. 15 is a time chart showing timings in operation of the solid-state imaging device 3 according to the fifth embodiment of the present invention;

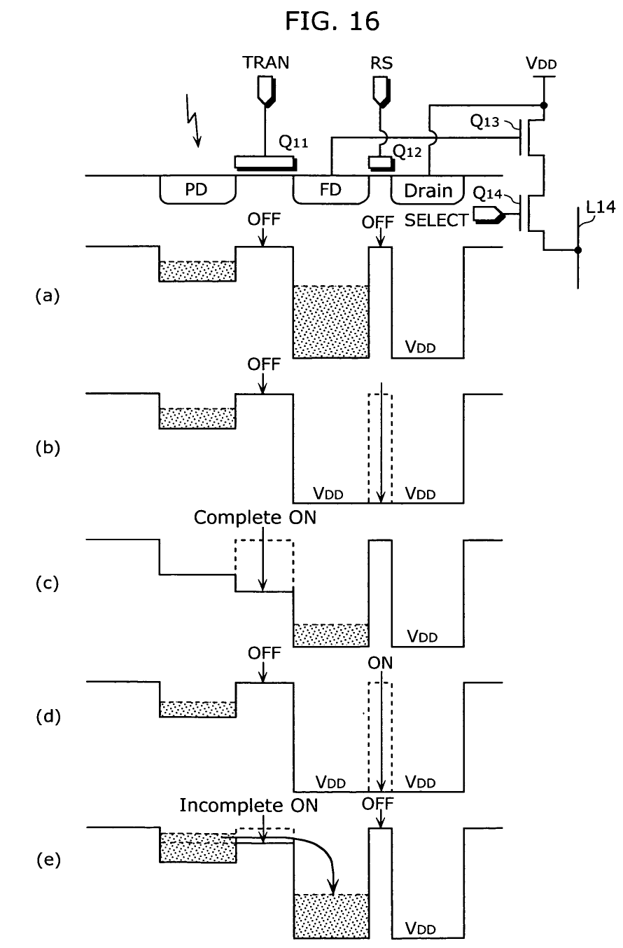

FIG. 16 is a diagram showing status of electric charges at main timings in FIG. 15;

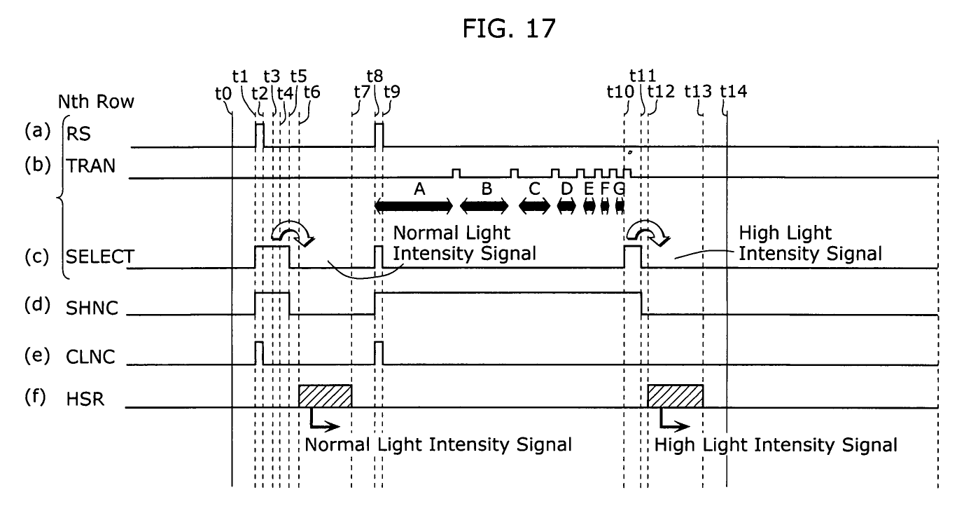

FIG. 17 is a time chart showing timings in operation of a solid-state imaging device according to the sixth embodiment of the present invention;

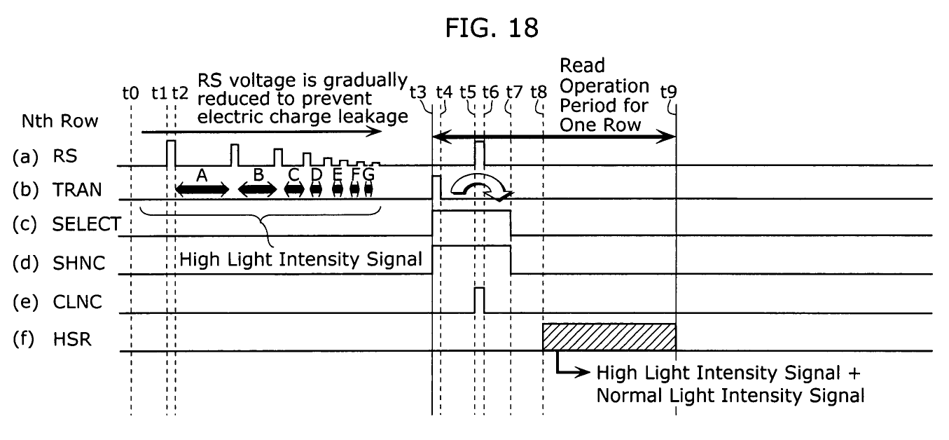

FIG. 18 is a time chart showing timings in operation of a solid-state imaging device according to the seventh embodiment of the present invention;

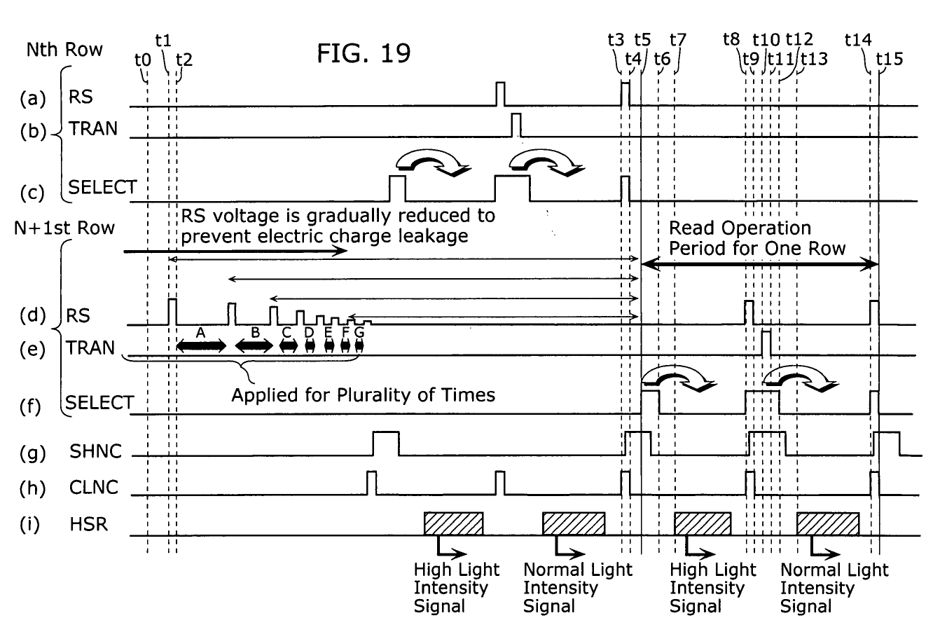

FIG. 19 is a time chart showing timings in operation of a solid-state imaging device according to the eighth embodiment of the present invention;

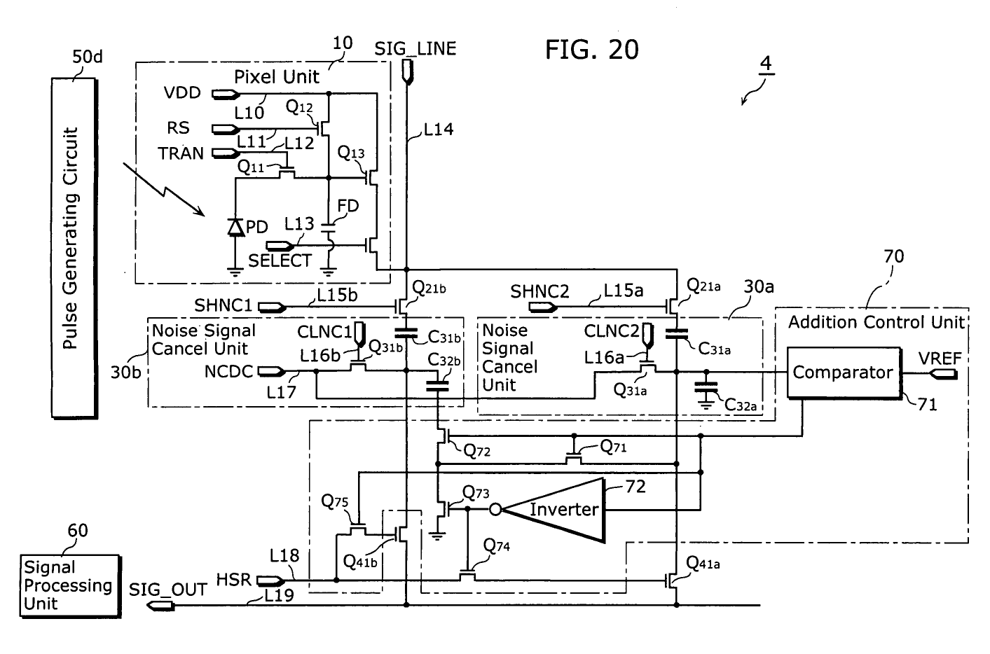

FIG. 20 is a circuit diagram showing a structure of a solid-state imaging device according to the ninth embodiment of the present invention;

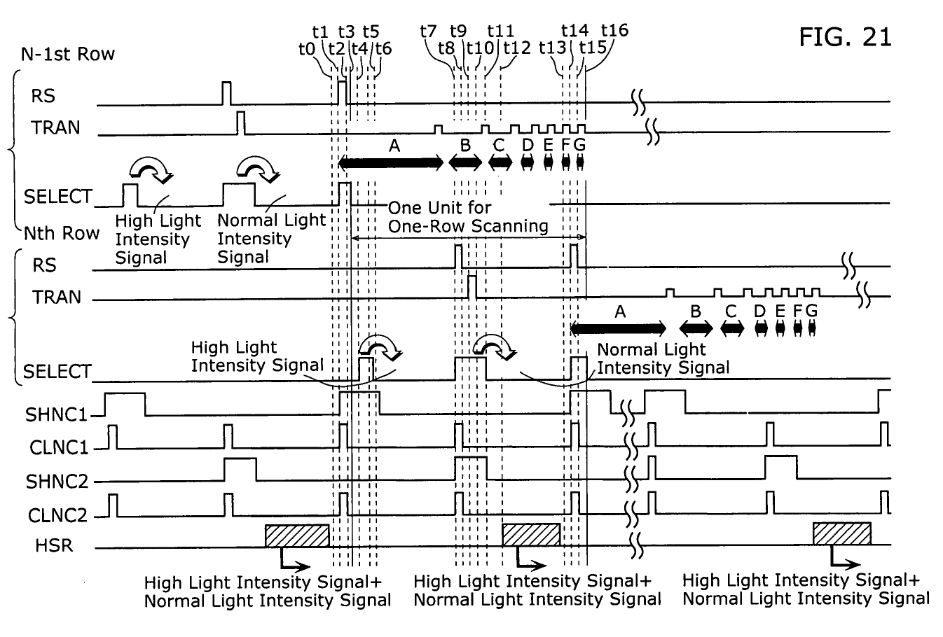

FIG. 21 is a time chart showing timings in operation of a solid-state imaging device 4 according to the ninth embodiment of the present invention; and

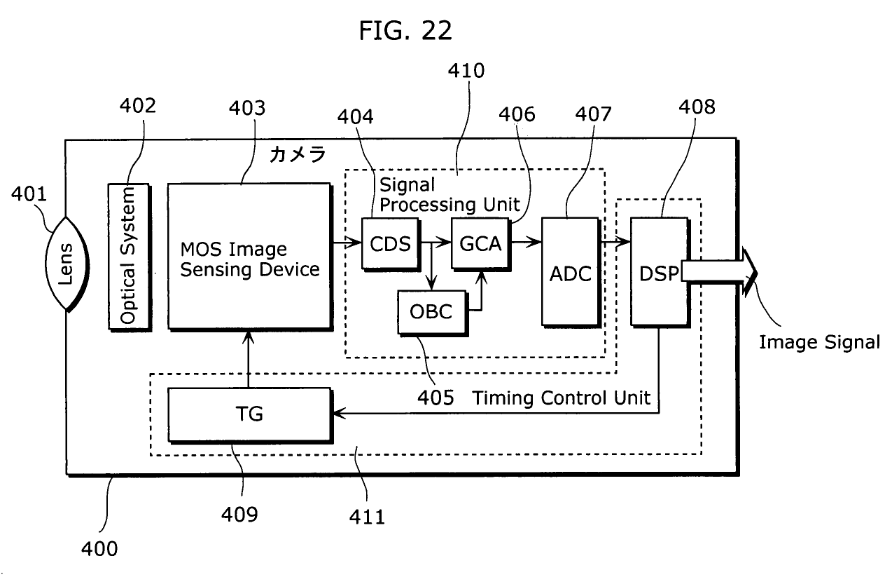

FIG. 22 is a diagram showing a structure of a camera using the solid-state imaging device of the above embodiments 1 to 9.

### DESCRIPTION OF THE PREFERRED EMBODIMENT(S)

The following describes the embodiments according to the prevent invention with reference to the drawings.

### First Embodiment

FIG. 3 is a circuit diagram showing a structure of a solid-state imaging device according to the first embodiment of the present invention. Note that a plurality of photoelectric transducers are actually arranged in rows and columns, but FIG. 3 shows one of the photoelectric transducers.

As shown in FIG. 3, the solid-state imaging device 1 is comprised of a pixel unit 10, a MOS transistor Q21, a noise signal cancel unit 30, a MOS transistor Q41, a pulse generating circuit 50a, a signal processing unit 60, a power line L10, a reset pulse supply signal line L11, a transfer pulse supply signal line L12, a row selection pulse supply signal line L13, a column direction common signal line L14, a sample hold pulse supply signal line L15, a capacitor initialization pulse supply signal line L16, a capacitor initialization bias supply line L17, a horizontal selection pulse supply signal line L18, a horizontal output signal line L19, and the like.

The pixel unit 10 is comprised of: a photoelectric transducer PD; a floating de-fusion FD as an accumulation region for accumulating electric charges; and a MOS transistor Q11 as a resetting means for initializing the electric charges accumulated in the floating de-fusion FD; a MOS transistor Q12; a MOS transistor Q13; and a MOS transistor Q14.

The noise signal cancel unit 30 is comprised of a MOS transistor Q31, a sampling capacitor C31, and a clamp capacitor C32.

Note that the MOS transistor Q11 is an enhancement-mode MOS transistor. A threshold value of the MOS transistor Q11 is set to be lower than threshold values of other enhancement-mode MOS transistors included in the solid-state imaging device 1. With such a structure, it is possible to easily control a complete transfer (or a whole transfer) and an incomplete transfer (or a partial transfer).

Note also that all parts included in a circuit in the solid-state imaging device 1 are NMOS transistors, and capacitor parts included in the circuit (the sampling capacitor C31 and the clamp capacitor C32) are also depression-mode NMOS capacitors. Thereby it is possible to easily manufacture the solid-state imaging device 1.

Regarding the photoelectric transducer PD in the pixel unit 10, an anode is connected to ground, and a cathode is connected to a drain of the MOS transistor Q11.

Regarding the MOS transistor Q11, a gate is connected to the transfer pulse supply signal line L12, and a source is connected to a source of the MOS transistor Q12 and a gate of the MOS transistor Q13. A region where the source of the MOS transistor Q11, the source of the MOS transistor Q12, and the gate of the MOS transistor Q13 are connected together is the floating de-fusion FD.

Regarding the MOS transistor Q12, a drain is connected to the power line L10, and a gate is connected to the reset pulse supply signal line L11. Regarding the MOS transistor Q13, a drain is connected to the power line L10, and a source is connected to a drain of the MOS transistor Q14. Regarding the MOS transistor Q14, a source is connected to the column direction common signal line L14, and a gate is connected to the row selection pulse supply signal line L13.

The MOS transistor Q21 serves as a switch for connecting and disconnecting the column direction common signal line L14 and the noise signal cancel unit 30. Regarding the MOS transistor Q21, a drain is connected to the column direction common signal line L14, a gate is connected to the sample hold pulse supply signal line L15, and a source is connected to one electrode of the sampling capacitor C31 in the noise signal cancel unit 30.

Regarding the MOS transistor Q31 in the noise signal cancel unit 30, a drain is connected to the capacitor initialization bias supply line L17, a gate is connected to the capacitor initialization pulse supply signal line L16, and a source is connected to the other electrode of the sampling capacitor C31, one electrode of the clamp capacitor C32, and a drain of the MOS transistor Q41.

Regarding the MOS transistor Q41, a source is connected to the horizontal output signal line L19, and a gate is connected to the horizontal selection pulse supply signal line L18.

The pulse generating circuit 50a generates various pulse signals for obtaining an image of one frame at predetermined timings. The generated pulse signals are applied to each gate of the MOS transistors Q11, Q12, Q14, Q21, Q31, and Q41 via each signal line L11 to L13 and L15 to L18.

More specifically, the pulse generating circuit 50a supplies a reset pulse RS to the gate of the MOS transistor Q12 in the pixel unit 10 via the reset pulse supply signal line L11, supplies a transfer pulse TRAN to the gate of the MOS transistor Q11, and supplies a row selection pulse SELECT to the gate of the MOS transistor Q14.

The pulse generating circuit 50a also supplies a sample hold pulse SHNC to the gate of the MOS transistor Q21.

The pulse generating circuit 50a further supplies a capacitor initialization pulse CLNC to the gate of the MOS transistor Q31.

The pulse generating circuit 50a still further supplies a horizontal selection pulse HSR to the gate of the MOS transistor Q41.

Furthermore, to the column direction common signal line L14, a signal SIG_LINE for transducing the electric charges outputted from the pixel unit 10 into a voltage is applied.

Still further, to the capacitor initialization bias supply line L17, a capacitor initialization bias supply signal NCDC for initializing the sampling capacitor C31 and the clamp capacitor C32 is applied.

When such pulse signals are applied, the MOS transistors Q11, Q12, Q14, Q21, Q31, and Q41 are driven, and signals are outputted on a row-by-row basis from each pixel unit 10 into the horizontal output signal line L19. Note that a transfer circuit is comprised of the MOS transistor Q11 and the pulse generating circuit 50a, and a reset circuit is comprised of the MOS transistor Q12 and the pulse generating circuit 50a.

The signal processing unit 60 forms a signal outputted from each row via the horizontal output signal line L19 into one frame image.

Next, an operation of the solid-state imaging device 1 according to the present invention is described.

FIG. 4 is a time chart showing timings in the operation of the solid-state imaging device 1 according to the first embodiment of the present invention.

Here, (a) to (c) in FIG. 4 show a reset pulse RS, a transfer pulse TRAN, and a row selection pulse SELECT, respectively, which are outputted from the pulse generating circuit 50a to the pixel unit 10 in the Nth row. (d) to (f) in FIG. 4 show a reset pulse RS, a transfer pulse TRAN, and a row selection pulse SELECT, respectively, which are outputted from the pulse generating circuit 50a to the pixel unit 10 in the N+1st row. (g) in FIG. 4 shows a sample hold pulse SHNC which is outputted from the pulse generating circuit 50a to the MOS transistor Q21. (h) in FIG. 4 shows a capacitor initialization pulse CLNC which is outputted from the pulse generating circuit 50a to the MOS transistor Q31. (i) in FIG. 4 shows a horizontal selection pulse HSR which is sequencially outputted from the pulse generating circuit 50a to the MOS transistor Q41 on each column.

The pulse generating circuit 50a turns all pulses OFF at time t0. Note that, immediately prior to the time t0, as shown in (a) of FIG. 5, electric charges proportional to normal light intensity are accumulated in the photoelectric transducer PD in the pixel unit 10 in the Nth row, and electric charges proportional to high light intensity are accumulated in the floating de-fusion FD.

Next, by the pulse generating circuit 50a, at time t1, the transfer pulse TRAN and the row selection pulse SELECT for the pixel unit 10 in the Nth row are turned ON, and also the sample hold pulse SHNC is turned ON. Thereby the MOS transistors Q11, Q14, and Q21 in the pixel unit 10 in the Nth row are turned ON. Note that, at this timing, the transfer pulse TRAN is a pulse signal having a large value in order to turn the MOS transistor Q11 ON completely, and as shown in (b) of FIG. 5, all of the electric charges accumulated in the photoelectric transducer PD are transferred to the floating de-fusion FD.

Therefore, the electric charges proportional to normal light intensity are added with the electric charges proportional to high light intensity which are accumulated in the floating de-fusion FD during one frame period, and pixel signals having a voltage corresponding to the total electric charges are outputted to the column direction common signal line L14 via the MOS transistors Q13 and Q14 and then transferred to the noise signal cancel unit 30 via the MOS transistor Q21.

Next, by the pulse generating circuit 50a, after the transfer pulse TRAN for the pixel unit 10 in the Nth row is turned OFF at time t2, then from time t3 to time t4, the reset pulse RS for the pixel unit 10 in the Nth row is set to ON. Thereby, after the MOS transistor Q11 in the pixel unit 10 in the Nth row is turned OFF, the MOS transistor Q12 is turned ON. Therefore, as shown in (c) of FIG. 5, the floating de-fusion FD is reset by VDD, and a reset potential of the floating de-fusion FD is outputted to the column direction common signal line L14 via the MOS transistors Q13 and Q14 and then transferred to the noise signal cancel unit 30 via the MOS transistor Q21.

Here, the electric charges are re-distributed into the sampling capacitor C31 and the clamp capacitor C32, and a voltage in which a threshold difference of the MOS transistor Q13 is eliminated from the re-distributed electric charges is obtained.

Furthermore, by the pulse generating circuit 50a, from time t3 to time t4, the capacitor initialization pulse CLNC is set to ON. Thereby the MOS transistor Q31 is turned ON, and the sampling capacitor C31 and the clamp capacitor C32 are applied with the capacitor initialization bias supply signal NCDC.

Next, by the pulse generating circuit 50a, at time t5, the row selection pulse SELECT and the sample hold pulse SHNC for the pixel unit 10 in the Nth row are turned OFF. Thereby, the MOS transistor Q21 is turned OFF.

Then, by the pulse generating circuit 50a, from time t6 to time t7, the horizontal selection pulse HSR for each column is sequentially turned ON. Thereby the MOS transistor Q41 in each column is turned ON sequentially, then one horizontal scanning is performed for signal lines in every column, and a pixel signal of one row is outputted to the horizontal output signal line L19.

After that, by the pulse generating circuit 50a, during one frame period, the transfer pulse TRAN for the pixel unit 10 in the Nth row is turned ON for multiple times by a voltage lower than a normal pulse (Complete ON). In other words, the transfer pulse TRAN is turned ON incompletely. Note that in the first embodiment, as shown in FIG. 4, it is seen a case where the transfer pulse TRAN is turned ON for multiple times by a voltage lower than the normal pulse during one horizontal period in the Next N+1st row.

Thereby, the almost saturated electric charges accumulated in the photoelectric transducer PD are passed through a gate potential of the MOS transistor Q11 and accumulated in the floating de-fusion FD.

More specifically, as shown in (d) of FIG. 5, slightly prior to when the electric charges accumulated in the photoelectric transducer PD overflow, the MOS transistor Q11 is turned ON incompletely, so that electric charges exceeding a predetermined amount are gradually transferred to the floating de-fusion FD beforehand.

The transfer pulse TRAN gradually shortens an interval between the ON states, for example, from a period A to a period B. In a case where incident light has intensity whose proportional electric charge amount is slightly larger than a normal saturated electric charge amount, the electric charges are accumulated in the floating de-fusion FD during a long accumulation period such as the period A. On the other hand, in a case where incident light has intensity whose proportional electric charge amount is much larger than the normal saturated electric charge amount, the electric charges are accumulated in the floating de-fusion FD also during a short accumulation period such as a period G. As a result, by the transfer pulse TRAN during all periods A to G, the electric charges are added into the floating de-fusion FD.

Thus, by setting more accumulation periods which are gradually shortened during one frame period, for example, from the period A to the period G, it is possible to achieve a wider dynamic range when incident light has high intensity. By adding, for multiple times in signal detection processing from time t1 to time t5, the accumulation signals proportional to high intensity light which are accumulated in the floating de-fusion FD with the accumulation signals proportional to normal intensity light which have not passed through the gate potential of the MOS transistor Q11 for transferring electric charges, it is possible to obtain output characteristics as shown in FIGS. 6 and 7.

Note that the first embodiment has described that the electric charges proportional to high intensity light and the electric charges proportional to normal intensity light are added together in the floating de-fusion FD, and the total signals are outputted to the column direction common signal line L14, but the pulse generating circuit 50a may output the electric charges proportional to high intensity light and the electric charges proportional to normal intensity light separately from the floating de-fusion FD to the column direction common signal line L14.

### Second Embodiment

Next, a description is given for an operation in a case where the electric charges proportional to high intensity light and the electric charges proportional to normal intensity light are outputted separately from the floating de-fusion FD to the column direction common signal line L14.

FIG. 8 is a time chart showing timings in operation of the solid-state imaging device 1 according to the second embodiment of the present invention.

Here, (a) to (c) in FIG. 8 show a reset pulse RS, a transfer pulse TRAN, and a row selection pulse SELECT, respectively, which are outputted from the pulse generating circuit 50a to the pixel unit 10 in the N−1st row. (d) to (f) in FIG. 8 show a reset pulse RS, a transfer pulse TRAN, and a row selection pulse SELECT, respectively, which are outputted from the pulse generating circuit 50a to the pixel unit 10 in the Nth row. (g) in FIG. 8 shows a sample hold pulse SHNC which is outputted from the pulse generating circuit 50a to the MOS transistor Q21. (h) in FIG. 8 shows a capacitor initialization pulse CLNC which is outputted from the pulse generating circuit 50a to the MOS transistor Q31. (i) in FIG. 8 shows a horizontal selection pulse HSR which is sequentially outputted from the pulse generating circuit 50a to the MOS transistor Q41 on each column.

Timings in FIG. 8 differ from the timings in FIG. 4 in that the pulse generating circuit 50a outputs the electric charges proportional to high intensity light and the electric charges proportional to normal intensity light separately to the horizontal output signal line L19 so that the operation is hardly affected by dark currents.

The pulse generating circuit 50a turns all pulses OFF at time t0.

By the pulse generating circuit 50a, at time t1, the transfer pulse TRAN and the row selection pulse SELECT for the pixel unit 10 in the N−1st row are turned ON, and also the sample hold pulse SHNC and the capacitor initialization pulse CLNC are turned ON. Thereby the MOS transistor Q12, the MOS transistors Q14, Q21, and Q31 are turned ON. Then, by the pulse generating circuit 50a, at time t2, the reset pulse RS for the pixel unit 10 in the N−1st row is turned OFF, and also the capacitor initialization pulse CLNC is turned OFF. Thereby the MOS transistors Q12 and Q31 are turned OFF. Therefore, an initialization potential of the floating de-fusion FD for the pixel unit 10 in the N−1st row is outputted to the column direction common signal line L14 via the MOS transistors Q13 and Q14 in the pixel unit 10 in the N−1st row.

At this timing, potentials in the sampling capacitor C31 and the clamp capacitor C32 are detected and replaced with initialization potentials. In other words, the initialization signal for the pixel unit 10 in the N−1st row is used for the pixel unit 10 in the Nth row. By the pulse generating circuit 50a, at time t3, the row selection pulse SELECT for the pixel unit 10 in the N−1st row is turned OFF.

It is assumed that, in the pixel unit 10 in the Nth row, immediately prior to time t4, as shown in (a) of FIG. 9, the electric charges proportional to normal intensity light are accumulated in the photoelectric transducer PD and the electric charges proportional to high intensity light are accumulated in the floating de-fusion FD.

Next, by the pulse generating circuit 50a, from time t4 to time t5, the row selection pulse SELECT is set to ON to turn the MOS transistor Q14 ON in the pixel unit 10 in the Nth row, and signals proportional to high intensity light (hereinafter, referred to as “high light intensity signal”) are outputted to the column direction common signal line L14 via the MOS transistors Q13 and Q14. Here, a difference between the previously set initialization potential and the potential of the sampling capacitor C31 and the clamp capacitor C32 is detected.

By the pulse generating circuit 50a, after the sample hold pulse SHNC is turned OFF to turn the MOS transistor Q21 OFF at time t6, then from time t7 to time t8, one horizontal scanning is performed for signal lines in every column. Here, a signal component is obtained by detecting all high light intensity signals.

Next, by the pulse generating circuit 50a, at time t9, the rest pulse RS, the row selection pulse SELECT, and the capacitor initialization pulse CLNC are turned ON to turn the MOS transistors Q12, Q14, and Q31 ON, then at time t10, the rest pulse RS and the capacitor initialization pulse CLNC are turned OFF to turn the MOS transistors Q12 and Q31 OFF, and after that, a initialization potential of the floating de-fusion FD is outputted to the column direction common signal line L14 via the MOS transistors Q13 and Q14. Here, potentials of the sampling capacitor C31 and the clamp capacitor C32 are detected and replaced with an initialization potential.

From time till to time t12, the transfer pulse TRAN is set to ON to turn the MOS transistor Q11 ON, and a signal proportional to normal intensity light (hereinafter, referred to as “normal light intensity signal”) is outputted to the column direction common signal line L14 via the MOS transistors Q13 and Q14.

More specifically, the floating de-fusion FD is reset as shown in (b) of FIG. 9, the MOS transistor Q11 is turned ON completely as shown in (c) of FIG. 9, the electric charges proportional to normal intensity light which are accumulated in the photoelectric transducer PD are transferred to the floating de-fusion FD, and then the normal light intensity signal is outputted to the column direction common signal line L14.

Here, a difference between the previously set initialization potential and the potential of the sampling capacitor C31 and the clamp capacitor C32 is detected.

After the row selection pulse SELECT is turned OFF to turn the MOS transistor Q14 at time t13 OFF, then from time t14 to time t15, one horizontal scanning is performed for signal lines in every column. Here, a signal component is obtained by detecting all high light intensity signals.

Accordingly, it is possible to perform two horizontal transfers for transferring the high light intensity signal component and the normal light intensity signal component separately and at a high speed.

Note that, by the pulse generating circuit 50a, at time t16, the reset pulse RS, the row selection pulse SELECT, the sample hold pulse SHNC, and the capacitor initialization pulse CLNC are turned ON to turn the MOS transistors Q12, Q14, Q21, and Q31 ON in the pixel unit 10 in the Nth row, then as shown in (d) of FIG. 9, the floating de-fusion FD is reset by VDD, and the initialization potential of the floating de-fusion FD is outputted to the column direction common signal line L14 via the MOS transistors Q13 and Q14, thereby generating an initialization voltage for detecting the high light intensity signal of the photoelectric transducer PD in the pixel unit 10 in the N+1st row.

Then, by the pulse generating circuit 50a, after the reset pulse RS and the capacitor initialization pulse CLNC are turned OFF to turn the MOS transistors Q12 and Q31 OFF in the pixel unit 10 in the Nth row at time t17, then at time t18, the row selection pulse SELECT is turned OFF to turn the MOS transistor Q14 OFF in the pixel unit 10 in the Nth row, and after that, during one frame period, the transfer pulse TRAN is turned ON for multiple times by a voltage lower than a normal pulse, so that, as shown in (e) of FIG. 9, electric charges which have passed through the gate potential of the MOS transistor Q11 for transferring electric charges are accumulated in the floating de-fusion FD.

The transfer pulse TRAN gradually shortens a interval between the ON states, for example, from a period A to a period B. In a case where incident light has intensity whose proportional electric charge amount is slightly larger than a normal saturated electric charge amount, the electric charges are accumulated in the floating de-fusion FD during a long accumulation period such as the period A. On the other hand, in a case where incident light has intensity whose proportional electric charge amount is much larger than the normal saturated electric charge amount, the electric charges are accumulated in the floating de-fusion FD also during a short accumulation period such as a period G. As a result, by the transfer pulse TRAN during all periods A to G, the electric charges are added into the floating de-fusion FD.

Thus, by setting more accumulation periods which are gradually shortened during one frame period, for example, from the period A to the period G, it is possible to achieve a wider dynamic range when incident light has high intensity.

Thereby the accumulation signals proportional to high intensity light which are accumulated in the floating de-fusion FD are transferred from time t7 to time t8, and the accumulation signals proportional to normal intensity light which have not passed through the gate potential of the MOS transistor Q11 for transferring electric charges are transferred from time t14 to time t15. By adding those two signal components together in the signal processing unit 60 in a later stage, it is possible to obtain the output characteristics as shown in FIGS. 6 and 7.

Moreover, in a case where the accumulation signal proportional to normal intensity light is not more than a predetermined amount in the signal processing unit 60, by setting the accumulation signal proportional to high intensity light not to be added, thereby eliminating a component of the accumulation signal proportional to high intensity light which contains a dark current component that results from longtime exposure and is noticeable when incident light has low intensity, in order to output only the accumulation signal proportional to normal intensity light, so that it is possible to achieve the wider dynamic range with little dark currents.

### Third Embodiment

Next, a solid-state imaging device according to the third embodiment of the present invention is described.

FIG. 10 is a circuit diagram showing a structure of the solid-state imaging device according to the third embodiment of the present invention. Note that a plurality of pixel units are actually arranged in rows and columns, but FIG. 10 shows one of the pixel units. Note that the reference numerals in FIG. 3 are assigned to identical elements in FIG. 10 so that the details of those elements are same as described above.

The third embodiment differs from the second embodiment in that the signals proportional to high intensity light and the signals proportional to normal intensity light are separately detected by noise signal cancel units 30a and 30b formed in a solid-state imaging device 2, and that an in-built addition control unit 70 (a comparator 71) determines whether or not the signals proportional to high intensity light is added to the signals proportional to normal intensity light.

As shown in FIG. 10, the solid-state imaging device 2 is comprised of a pixel unit 10, MOS transistors Q21a and Q21b, the noise signal cancel units 30a and 30b, the addition control unit 70, MOS transistors Q41a and Q41b, a signal processing unit 60, a power line L10, a reset pulse supply signal line L11, a transfer pulse supply signal line L12, a row selection pulse supply signal line L13, a column direction common signal line L14, sample hold pulse supply signal lines L15a and L15b, capacitor initialization pulse supply signal lines L16a and L16b, a capacitor initialization bias supply line L17, a horizontal selection pulse supply signal line L18, and a horizontal output signal line L19, and the like.

The noise signal cancel unit 30a is, like the noise signal cancel unit 30, comprised of a MOS transistor Q31a, a sampling capacitor C31a, and a clamp capacitor C32a. The noise signal cancel unit 30b is, like the noise signal cancel unit 30, comprised of a MOS transistor Q31b, a sampling capacitor C31b, and a clamp capacitor C32b.

The addition control unit 70 is comprised of the comparator 71, an inverter 72, MOS transistors Q71, Q72, Q73, Q74, and Q75.

The column direction common signal line L14 is connected to both a drain of the MOS transistor Q21a and a drain of the MOS transistor Q21b. Regarding the MOS transistor Q21a, a gate is connected to the sample hold pulse supply signal line L15a, and a source is connected to one terminal of the sampling capacitor C31a in the noise signal cancel unit 30a. Regarding the MOS transistor Q21b, a gate is connected to the sample hold pulse supply signal line L15b, a source is connected to one terminal of the sampling capacitor C31b in the noise signal cancel unit 30b.

Regarding the MOS transistor Q31a in the noise signal cancel unit 30a, a drain is connected to the capacitor initialization bias supply line L17, a source is connected to the sampling capacitor C31a, the clamp capacitor C32a, and a drain of the MOS transistor Q41a, and a gate is connected to the capacitor initialization pulse supply signal line L16a. Regarding the MOS transistor Q31b in the noise signal cancel unit 30b, a drain is connected to the capacitor initialization bias supply line L17, a source is connected to the sampling capacitor C31b, the clamp capacitor C32b, and a drain of the MOS transistor Q41b, and a gate is connected to the capacitor initialization pulse supply signal line L16b.

The comparator 71 in the addition control unit 70 compares a voltage of the clamp capacitor C32a with a predetermined reference voltage VREF, and in a case where the voltage of the clamp capacitor C32a is higher than the reference voltage VREF, a high-level signal is outputted, and in a case where the voltage of the clamp capacitor C32a is lower than the reference voltage VREF, a low-level signal is outputted. The inverter 72 reverse the level of the signal outputted from the comparator 71.

Regarding the MOS transistor Q71, a gate is connected to an output of the comparator 71, a drain is connected to a source of the MOS transistor Q31a, and a source is connected to a source of the MOS transistor Q72 and a drain of the MOS transistor Q73. Regarding the MOS transistor Q72, a gate is connected to the output of comparator 71, and a drain is connected to the clamp capacitor C32b. Regarding the MOS transistor Q73, a gate is connected to an output of the inverter 72, and a source is connected to ground GND. Regarding the MOS transistor Q74, a gate is connected to the output of the inverter 72, a drain is connected to the horizontal selection pulse supply signal line L18, and a source is connected to a gate of the MOS transistor Q41a. Regarding the MOS transistor Q75, a gate is connected to the output of the comparator 71, a drain is connected to the horizontal selection pulse supply signal line L18, and a source is connected to a gate of the MOS transistor Q41b.

Regarding the MOS transistor Q41a, a drain is connected to the sampling capacitor C31a and the clamp capacitor C32a, and a source is connected to the horizontal output signal line L19. Regarding the MOS transistor Q41b, a drain is connected to the sampling capacitor C31b and the clamp capacitor C32b, and a source is connected to the horizontal output signal line L19.

The pulse generating circuit 50b outputs a reset pulse RS to the reset pulse supply signal line L11, a transfer pulse TRAN to the transfer pulse supply signal line L12, and a row selection pulse SELECT to the row selection pulse supply signal line L13.

The pulse generating circuit 50b further outputs a sample hold pulse SHNC1 to the sample hold pulse supply signal line L15b, and a capacitor initialization pulse CLNC1 to the capacitor initialization pulse supply signal line L16b. The pulse generating circuit 50b still further outputs a sample hold pulse SHNC2 to the sample hold pulse supply signal line L15a, and a capacitor initialization pulse CLNC2 to the capacitor initialization pulse supply signal line L16a. The pulse generating circuit 50b still further outputs a horizontal selection pulse HSR to the horizontal selection pulse supply signal line L18.

Thereby, based on a determination result by the comparator 71 in the addition control unit 70, a signal proportional to normal intensity light or a signal obtained by adding the signal proportional to high intensity light to the signal proportional to normal intensity light is outputted to the horizontal output signal line L19.

Next, an operation of the solid-state imaging device 2 according to the present invention is described.

FIG. 11 is a time chart showing timings in operation of a solid-state imaging device 2 according to the third embodiment of the present invention.

Here, (a) to (c) in FIG. 11 show a reset pulse RS, a transfer pulse TRAN, and a row selection pulse SELECT, respectively, which are outputted from the pulse generating circuit 50b to the pixel unit 10 in the N−1st row. (d) to (f) in FIG. 11 show a reset pulse RS, a transfer pulse TRAN, and a row selection pulse SELECT, respectively, which are outputted from the pulse generating circuit 50b to the pixel unit 10 in the Nth row. (g) in FIG. 11 shows a sample hold pulse SHNC1 which is outputted from the pulse generating circuit 50b to the MOS transistor Q21b. (h) in FIG. 11 shows a capacitor initialization pulse CLNC1 which is outputted from the pulse generating circuit 50b to the MOS transistor Q31b. (i) in FIG. 11 shows a sample hold pulse SHNC2 which is sequentially outputted from the pulse generating circuit 50b to the MOS transistor Q21a. (j) in FIG. 11 shows a capacitor initialization pulse CLNC2 which is outputted from the pulse generating circuit 50b to the MOS transistor Q31a. (k) in FIG. 11 shows a horizontal selection pulse HSR which is sequentially outputted from the pulse generating circuit 50b to the MOS transistors Q41a and Q41b on each column.

The pulse generating circuit 50b turns all pulses OFF at time t0.

By the pulse generating circuit 50b, at time t1, the reset pulse RS, the row selection pulse SELECT for the pixel unit 10 in the N−1st row are turned ON, and also the sample hold pulse SHNC1 and the capacitor initialization pulse CLNC1 are turned ON, then at time t2, the reset pulse RS and the capacitor initialization pulse CLNC1 for the pixel unit 10 in the N−1st row are turned OFF, and after that, an initialization potential of the floating de-fusion FD in the pixel unit 10 in the N−1st row is outputted to the column direction common signal line L14 via the MOS transistors Q13 and Q14 in the pixel unit 10 in the N−1st row.

At this timing, potentials in the sampling capacitor C31b and the clamp capacitor C32b are detected and replaced with an initialization potential.

By the pulse generating circuit 50b, after the row selection pulse SELECT for the pixel unit 10 in the N−1st row is turned OFF at time t3, then from time t4 to time t5, the row selection pulse SELECT for the pixel unit 10 in the Nth row is turned ON, and a high light intensity signal is outputted to the column direction common signal line L14 via the MOS transistors Q13 and Q14.

Here, a difference between the previously set initialization potential and the potential of the sampling capacitor C31 and the clamp capacitor C32 is detected.

By the pulse generating circuit 50b, at time t6, in order not to input the signal passed through the column direction common signal line L14 into the noise signal cancel unit 30b, the sample hold pulse SHNC1 is turned OFF to turn the MOS transistor Q21b OFF.

By the pulse generating circuit 50b, at time t7, the reset pulse RS and the row selection pulse SELECT for the pixel unit 10 in the Nth row are turned ON and also the sample hold pulse SHNC2 and the capacitor initialization pulse CLNC2 are turned ON, then at time t8, the reset pulse RS for the pixel unit 10 in the Nth row is turned OFF and also the capacitor initialization pulse CLNC2 is turned OFF, and after that, an initialization potential of the floating de-fusion FD in the pixel unit 10 in the Nth row is outputted to the column direction common signal line L14 via the MOS transistors Q13 and Q14.

Here, potentials of the sampling capacitor C31a and the clamp capacitor C32a are detected and replaced with an initialization potential.

By the pulse generating circuit 50b, from t9 to time 10, the transfer pulse TRAN for the pixel unit 10 in the Nth row is turned ON, and a normal light intensity signal is outputted to the column direction common signal line L14 via the MOS transistors Q13 and Q14.

Here, a difference between the previously set initialization potential and the potential of the sampling capacitor C31 and the clamp capacitor C32 is detected. At this timing, the comparator 71 compares a difference voltage with a reference voltage VREF, and in a case where the difference voltage is higher than a certain level voltage (a saturation voltage in this case), the comparator 71 outputs a high-level voltage. Thereby, the MOS transistors Q71, Q72, and Q75 become ON state, and the MOS transistors Q73 and Q74 become OFF state, so that a voltage of the clamp capacitor C32a is added with a voltage of the clamp capacitor C32b.

Furthermore, by the pulse generating circuit 50b, after the row selection pulse SELECT and the sample hold pulse SHNC2 are turned OFF at time t11, then from time t12 to time t13, one horizontal scanning is performed for signal lines in every column. Here, the horizontal selection pulse HSR is applied only to the MOS transistor Q41b, so that signal components to be transferred horizontally are obtained by adding a component of the normal light intensity signal with a component of all of the high light intensity signals.

On the other hand, by the pulse generating circuit 50b, from time t9 to time t10, the transfer pulse TRAN is turned ON to output a normal light intensity signal to the column direction common signal line L14 via the MOS transistors Q13 an Q14, and when a difference between the previously set initialization potential and the potential of the sampling capacitor C31 and the clamp capacitor C32 is detected, the comparator 71 compares a difference voltage with a reference voltage VREF, and in a case where the difference voltage is lower than a certain level voltage (a saturation voltage in this case), the comparator 71 outputs a low-level voltage.

Thereby, the MOS transistors Q71, Q72, and Q75 become OFF state, and the MOS transistors Q73 and Q74 become ON state, so that only a voltage of the clamp capacitor C32a is used to perform one horizontal scanning for signal lines in every column from time t12 to time t13.

As described above, the comparator 71 can determine whether incident light has high intensity or normal intensity in the solid-state imaging device 2, thereby eliminating a component of the accumulation signal proportional to high intensity light which contains a dark current component that results from longtime exposure and is noticeable when incident light has low intensity, in order to output only the accumulation signal proportional to normal intensity light, so that it is possible to achieve the wider dynamic range with little dark currents.

Note that, by the pulse generating circuit 50b, at time t14, the reset pulse RS and the row selection pulse SELECT for the pixel unit 10 in the Nth row are turned ON and also the capacitor initialization pulse CLNC1 is turned ON in order to output the initialization potential of the floating de-fusion FD to the column direction common signal line L14 via the MOS transistors Q13 and Q14, thereby generating an initialization voltage for detecting a high light intensity signal of the photoelectric transducer PD in the pixel unit 10 in the Nth row.

After the reset pulse RS and the capacitor initialization pulse CLNC1 are turned OFF at time t15, then the row selection pulse SELECT is turned OFF at time t16, and after that the transfer pulse TRAN is turned ON for multiple times during one frame period by a voltage lower than the normal pulse, so that the electric charges which have passed through the gate potential of the MOS transistor Q11 for transferring electric charges are accumulated in the floating de-fusion FD. The transfer pulse TRAN gradually shortens a interval between the ON states, for example, from a period A to a period B. In a case where incident light has intensity whose proportional electric charge amount is slightly larger than a normal saturated electric charge amount, the electric charges are accumulated in the floating de-fusion FD during a long accumulation period such as the period A. On the other hand, in a case where incident light has intensity whose proportional electric charge amount is much larger than the normal saturated electric charge amount, the electric charges are accumulated in the floating de-fusion FD also during a short accumulation period such as a period G. As a result, by the transfer pulse TRAN during all periods A to G, the electric charges are added into the floating de-fusion FD. Thus, by setting more accumulation periods which are gradually shortened during one frame period, for example, from the period A to the period G, it is possible to achieve a wider dynamic range when incident light has high intensity.

Thereby the accumulation signals proportional to high intensity light which are accumulated in the floating de-fusion FD are transferred from time t4 to time t5, and the accumulation signals proportional to normal intensity light which have not passed through the gate potential of the MOS transistor Q11 for transferring electric charges are transferred from time t9 to time t10. Those two signal components are held in separate noise cancel circuits, and in a case where those two signal components are added together based on a voltage level examination by the comparator 71, it is possible to obtain the output characteristics as shown in FIGS. 6 and 7. It is also possible to eliminate a component of the accumulation signal proportional to high intensity light which contains a dark current component that results from longtime exposure and is noticeable when incident light has low intensity, in order to output only the accumulation signal proportional to normal intensity light, so that the wider dynamic range with little dark currents can be achieved.

Note that, in the first to third embodiments, by setting that the MOS transistor Q11 as a transferring means for transferring electric charges is an enhancement-mode MOS transistor and a threshold value of the MOS transistor Q11 is lower than threshold values of other enhancement-mode MOS transistors, and the MOS transistor Q12 for setting an accumulation region for accumulating electric charges with a voltage of the power line is a depression-mode MOS transistor, it is possible to provide a solid-state imaging device which can show the characteristics more easily.

Note also that, in the first to third embodiments, by setting that all circuits are NMOS transistors and that a noise cancel capacitor is a depression-mode NMOS capacitor, it is possible to reduce a manufacturing cost and to provide a solid-state imaging device with little dark currents.

### Fourth Embodiment

FIG. 12 is a circuit diagram showing a structure of a solid-state imaging device according to the fourth embodiment of the present invention. Note that a plurality of photoelectric transducers are actually arranged in rows and columns, but FIG. 12 shows one of the photoelectric transducers.

As shown in FIG. 12, a solid-state imaging device 3 is comprised of a pixel unit 10, a MOS transistor Q21, a noise signal cancel unit 30, a MOS transistor Q41, a pulse generating circuit 50c, a signal processing unit 60, a power line L10, a reset pulse supply signal line L11, a transfer pulse supply signal line L12, a row selection pulse supply signal line L13, a column direction common signal line L14, a sample hold pulse supply signal line L15, a capacitor initialization pulse supply signal line L16, a capacitor initialization bias supply line L17, a horizontal selection pulse supply signal line L18, a horizontal output signal line L19, and the like.

The pixel unit 10 is comprised of: a photoelectric transducer PD; a floating de-fusion FD as an accumulation region for accumulating electric charges; and a MOS transistor Q11 as a transferring means for transferring the electric charges; a MOS transistor Q12; a MOS transistor Q13; and a MOS transistor Q14.

The noise signal cancel unit 30 is comprised of the MOS transistor Q31, the sampling capacitor C31, and a clamp capacitor C32.

Note that the MOS transistor Q11 is an enhancement-mode MOS transistor. A threshold value of the MOS transistor Q11 is set to be lower than threshold values of other enhancement-mode MOS transistors included in the solid-state imaging device 3. With such a structure, it is possible to easily control a complete transfer and an incomplete transfer.

Note also that all parts included in a circuit of the solid-state imaging device 3 are NMOS transistors, and capacitor parts included in the circuit (the sampling capacitor C31 and the clamp capacitor C32) are also depression-mode NMOS capacitors. Thereby it is possible to easily manufacture the solid-state imaging device 3.

Regarding the photoelectric transducer PD in the pixel unit 10, an anode is connected to ground, and a cathode is connected to a drain of the MOS transistor Q11.

Regarding the MOS transistor Q11, a gate is connected to the transfer pulse supply signal line L12, and a source is connected to a source of the MOS transistor Q12 and a gate of the MOS transistor Q13. A region where the source of the MOS transistor Q11, the source of the MOS transistor Q12, and the gate of the MOS transistor Q13 are connected together is the floating de-fusion FD.

Regarding the MOS transistor Q12, a drain is connected to the power line L10, and a gate is connected to the reset pulse supply signal line L11. Regarding the MOS transistor Q13, a drain is connected to the power line L10, and a source is connected to a drain of the MOS transistor Q14. Regarding the MOS transistor Q14, a source is connected to the column direction common signal line L14, and a gate is connected to the row selection pulse supply signal line L13.

The MOS transistor Q21 serves as a switch for connecting and disconnecting the column direction common signal line L14 and the noise signal cancel unit 30. Regarding the MOS transistor Q21, a drain is connected to the column direction common signal line L14, a gate is connected to the sample hold pulse supply signal line L15, a source is connected to one electrode of the sampling capacitor C31 in the noise signal cancel unit 30.

Regarding the MOS transistor Q31 in the noise signal cancel unit 30, a drain is connected to the capacitor initialization bias supply line L17, a gate is connected to the capacitor initialization pulse supply signal line L16, and a source is connected to the other electrode of the sampling capacitor C31, one electrode of the clamp capacitor C32, and a drain of the MOS transistor Q41.

Regarding the MOS transistor Q41, a source is connected to the horizontal output signal line L19, and a gate is connected to the horizontal selection pulse supply signal line L18.

The pulse generating circuit 50c generates various pulse signals at predetermined timings to obtain an image of one frame. The generated pulse signals are applied to each gate of the MOS transistors Q11, Q12, Q14, Q21, Q31, and Q41 via each signal line L11 to L13 and L15 to L18.

More specifically, the pulse generating circuit 50c supplies a reset pulse RS to the gate of the MOS transistor Q12 in the pixel unit 10 via the reset pulse supply signal line L11, supplies a transfer pulse TRAN to the gate of the MOS transistor Q11, and supplies a row selection pulse SELECT to the gate of the MOS transistor Q14.

Note that the reset pulse RS, the transfer pulse TRAN, and the row selection pulse SELECT shown in FIG. 12 are examples in a case of being used to scan the pixel unit 10 in the N+1st row, and those pulses are used in the same manner in other pixel units.

The pulse generating circuit 50c also supplies a sample hold pulse SHNC to a gate of the MOS transistor Q21.

The pulse generating circuit 50c further supplies a capacitor initialization pulse CLNC to a gate of the MOS transistor Q31.

The pulse generating circuit 50c still further supplies a horizontal selection pulse HSR to a gate of the MOS transistor Q41.

Moreover, to the column direction common signal line L14, a signal SIG_LINE for transducing the electric charges outputted from the pixel unit 10 into voltage is applied.

Furthermore, to the capacitor initialization bias supply line L17, a capacitor initialization bias supply signal NCDC for initializing the sampling capacitor C31 and the clamp capacitor C32 is applied.

When these pulse signals are applied, the MOS transistors Q11, Q12, Q14, Q21, Q31, and Q41 are driven, and signals are outputted on a row-by-row basis from each pixel unit 10 into the horizontal output signal line L19.

The signal processing unit 60 forms a signal outputted from each row via the horizontal output signal line L19 into one frame image.

Next, an operation of the solid-state imaging device 3 according to the present invention is described.

FIG. 13 is a time chart showing timings in operation of a solid-state imaging device 3 according to the fourth embodiment of the present invention;

Here, (a) to (c) in FIG. 13 show a reset pulse RS, a transfer pulse TRAN, and a row selection pulse SELECT, respectively, which are outputted from the pulse generating circuit 50c to the pixel unit 10 in the Nth row. (d) to (f) in FIG. 13 show a reset pulse RS, a transfer pulse TRAN, and a row selection pulse SELECT, respectively, which are outputted from the pulse generating circuit 50c to the pixel unit 10 in the N+1st row. (g) in FIG. 13 shows a sample hold pulse SHNC which is outputted from the pulse generating circuit 50c to the MOS transistor Q21. (h) in FIG. 13 shows a capacitor initialization pulse CLNC which is outputted from the pulse generating circuit 50c to the MOS transistor Q31. (i) in FIG. 4 shows a horizontal selection pulse HSR which is sequentially outputted from the pulse generating circuit 50c to the MOS transistor Q41 on each column.

The pulse generating circuit 50c turns all pulses OFF at time Note that, immediately prior to time t0, as shown in (a) of FIG. 14, electric charges proportional to normal light intensity are accumulated in the photoelectric transducer PD of the pixel unit 10 in the Nth row, and electric charges proportional to high light intensity are accumulated in the floating de-fusion FD.

Next, by the pulse generating circuit 50c, at time t1, the transfer pulse TRAN and the row selection pulse SELECT for the pixel unit 10 in the Nth row are turned ON, and also the sample hold pulse SHNC is turned ON. Thereby the MOS transistors Q11, Q14, and Q21 in the pixel unit 10 in the Nth row is turned ON. Note that, at this timing, the transfer pulse TRAN is a pulse signal having a large value in order to turn the MOS transistor Q11 ON completely, and as shown in (b) of FIG. 14, all electric charges accumulated in the photoelectric transducer PD are transferred to the floating de-fusion FD.

Therefore, the electric charges proportional to normal light intensity is added with the electric charges proportional to high light intensity which are accumulated in the floating de-fusion FD during one frame period, and a pixel signal having a voltage corresponding to the total electric charges are outputted to the column direction common signal line L14 via the MOS transistors Q13 and Q14 and then transferred to the noise signal cancel unit 30 via the MOS transistor Q21.

Next, by the pulse generating circuit 50c, at time t2, the transfer pulse TRAN for the pixel unit 10 in the Nth row is turned OFF, and then from time t3 to time t4, the reset pulse RS for the pixel unit 10 in the Nth row is set to ON. Thereby, after the MOS transistor Q11 in the pixel unit 10 in the Nth row is turned OFF, the MOS transistor Q12 is turned ON. Therefore, as shown in (c) of FIG. 14, the floating de-fusion FD is reset by VDD, and a reset potential of the floating de-fusion FD is outputted to the column direction common signal line L14 via the MOS transistors Q13 and Q14 and then transferred to the noise signal cancel unit 30 via the MOS transistor Q21.

Here, the electric charges are re-distributed into the sampling capacitor C31 and the clamp capacitor C32, and a voltage in which a threshold difference of the MOS transistor Q13 is eliminated from the re-distributed electric charges is obtained.

Furthermore, by the pulse generating circuit 50c, from time t3 to time t4, the capacitor initialization pulse CLNC is set to ON. Thereby the MOS transistor Q31 is turned ON, and the capacitor initialization bias supply signal NCDC is applied to the sampling capacitor C31 and the clamp capacitor C32.

Next, by the pulse generating circuit 50c, at time t5, the row selection pulse SELECT and the sample hold pulse SHNC for the pixel unit 10 on Nth row are turned OFF. Thereby the MOS transistor Q21 is turned OFF.

Then, by the pulse generating circuit 50c, from time t6 to time t7, the horizontal selection pulse HSR for each column is sequentially turned ON. Thereby the MOS transistor Q41 in each column is turned ON sequentially, one horizontal scanning is performed for signal lines in every column, and a pixel signal of one row is outputted to the horizontal output signal line L19. Then, the one horizontal period ends at time t8.

After that, during one frame period, from time t9 to time t10, the reset pulse RS is turned ON and the floating de-fusion FD is temporarily set to an initialization potential, and then by the pulse generating circuit 50c, during one frame period, the transfer pulse TRAN for the pixel unit 10 in the Nth row is turned ON for multiple times by a voltage lower than a normal pulse (Complete ON). In other words, the pulse generating circuit 50c, during a next one frame period, further eliminates electric charges accumulated in the floating de-fusion FD which result from smears, and then turns the MOS transistor Q11 ON completely. Note that in the fourth embodiment, as shown in FIG. 13, it is seen a case where the transfer pulse TRAN is turned ON for multiple times by a voltage lower than the normal pulse during one horizontal period in the next N+1st row.

Thereby the almost saturated electric charges accumulated in the photoelectric transducer PD are passed through a gate potential of the MOS transistor Q11 and accumulated in the floating de-fusion FD.

More specifically, slightly prior to when the electric charges accumulated in the photoelectric transducer PD overflow, the MOS transistor Q11 is turned ON incompletely as shown in (d) of FIG. 5, so that electric charges exceeding a predetermined amount are gradually transferred to the floating de-fusion FD beforehand.

The transfer pulse TRAN gradually shortens a interval between the ON states, for example, from a period A to a period B. In a case where incident light has intensity whose proportional electric charge amount is slightly larger than a normal saturated electric charge amount, the electric charges are accumulated in the floating de-fusion FD during a long accumulation period such as the period A. On the other hand, in a case where incident light has intensity whose proportional electric charge amount is much larger than the normal saturated electric charge amount, the electric charges are accumulated in the floating de-fusion FD also during a short accumulation period such as a period G. As a result, by the transfer pulse TRAN during all periods A to G, the electric charges are added into the floating de-fusion FD.

Thus, by setting more accumulation periods which are gradually shortened during one frame period, for example, from the period A to the period G, it is possible to achieve a wider dynamic range when incident light has high intensity. By adding, for multiple times in signal detection processing from time t1 to time t5, the accumulation signals proportional to high intensity light which are accumulated in the floating de-fusion FD with the accumulation signals proportional to normal intensity light which have not passed through the gate potential of the MOS transistor Q11 for transferring electric charges, it is possible to obtain output characteristics as shown in FIGS. 6 and 7.

Note that the fourth embodiment has described that the electric charges proportional to high intensity light and the electric charges proportional to normal intensity light are added together in the floating de-fusion FD, and the total signals are outputted to the column direction common signal line L14, but the pulse generating circuit 50c may output the electric charges proportional to high intensity light and the electric charges proportional to normal intensity light separately from the floating de-fusion FD to the column direction common signal line L14.

### Fifth Embodiment

Next, a description is given for an operation in a case where the electric charges proportional to high intensity light and the electric charges proportional to normal intensity light are outputted separately from the floating de-fusion FD to the column direction common signal line L14.

FIG. 15 is a time chart showing timings in operation of the solid-state imaging device 3 according to the fifth embodiment of the present invention.

Here, (a) to (c) in FIG. 15 show a reset pulse RS, a transfer pulse TRAN, and a row selection pulse SELECT, respectively, which are outputted from the pulse generating circuit 50c to the pixel unit 10 in the N−1st row. (d) to (f) in FIG. 15 show a reset pulse RS, a transfer pulse TRAN, and a row selection pulse SELECT, respectively, which are outputted from the pulse generating circuit 50c to the pixel unit 10 in the Nth row. (g) in FIG. 15 shows a sample hold pulse SHNC which is outputted from the pulse generating circuit 50c to the MOS transistor Q21. (h) in FIG. 15 shows a capacitor initialization pulse CLNC which is outputted from the pulse generating circuit 50c to the MOS transistor Q31. (i) in FIG. 15 shows a horizontal selection pulse HSR which is sequentially outputted from the pulse generating circuit 50c to the MOS transistor Q41 on each column. Timings in FIG. 15 differ from the timings in FIG. 13 in that the pulse generating circuit 50c outputs the electric charges proportional to high intensity light and the electric charges proportional to normal intensity light separately to the horizontal output signal line L19 so that the operation is hardly affected by dark currents.

The pulse generating circuit 50c turns all pulses OFF at time t0.

By the pulse generating circuit 50c, at time t1, the reset pulse RS and the row selection pulse SELECT for the pixel unit 10 in the N−1st row are turned ON, and also the sample hold pulse SHNC and the capacitor initialization pulse CLNC are turned ON. Thereby the MOS transistors Q12, Q14, Q21, and Q31 are turned ON. Then, by the pulse generating circuit 50c, at time t2, the reset pulse RS for the pixel unit 10 in the N−1st row is turned OFF, and also the capacitor initialization pulse CLNC is turned OFF. Thereby, the MOS transistors Q12 and Q31 are turned OFF. Therefore, an initialization potential of the floating de-fusion FD for the pixel unit 10 in the N−1st row is outputted to the column direction common signal line L14 via the MOS transistors Q13 and Q14 in the pixel unit 10 in the N−1st row.

Here, potentials in the sampling capacitor C31 and the clamp capacitor C32 are detected and replaced with the initialization potential. In other words, the initialization signal for the pixel unit 10 in the N−1st row is used for the pixel unit 10 in the Nth row. By the pulse generating circuit 50c, at time t3, the row selection pulse SELECT for the pixel unit 10 in the N−1st row is turned OFF.

It is assumed that, in the pixel unit 10 in the Nth row, immediately prior to time t4, as shown in (a) of FIG. 16, the electric charges proportional to normal intensity light are accumulated in the photoelectric transducer PD and the electric charges proportional to high intensity light are accumulated in the floating de-fusion FD.

Next, by the pulse generating circuit 50c, from time t4 to time t5, the row selection pulse SELECT is set to ON to turn the MOS transistor Q14 ON in the pixel unit 10 in the Nth row, and a signal proportional to high intensity light is outputted to the column direction common signal line L14 via the MOS transistors Q13 and Q14. Here, a difference between the previously set initialization potential and the potential of the sampling capacitor C31 and the clamp capacitor C32 is detected.

By the pulse generating circuit 50c, at time t5, the sample hold pulse SHNC is turned OFF to turn the MOS transistor Q21 OFF, and after that, from time t6 to time t7, one horizontal scanning is performed for signal lines in every column. Here, a signal component is obtained by detecting all high light intensity signals.

Next, by the pulse generating circuit 50c, at time t8, the rest pulse RS, the row selection pulse SELECT, the sample hold pulse SHNC, and the capacitor initialization pulse CLNC are turned ON to turn the MOS transistors Q12, Q14, and Q31 ON, and at time t9, the rest pulse RS and the capacitor initialization pulse CLNC are turned OFF to turn the MOS transistors Q12 and Q31 OFF, and then a initialization potential of the floating de-fusion FD is outputted to the column direction common signal line L14 via the MOS transistors Q13 and Q14. Here, potentials of the sampling capacitor C31 and the clamp capacitor C32 are detected and replaced with an initialization potential.

From time t10 to time t11, the transfer pulse TRAN is set to ON to turn the MOS transistor Q11 ON, and a normal light intensity signal is outputted to the column direction common signal line L14 via the MOS transistors Q13 and Q14.

More specifically, after resetting the floating de-fusion FD as shown in (b) of FIG. 16, the MOS transistor Q11 is turned ON completely as shown in (c) of FIG. 16, and the electric charges proportional to normal intensity light which are accumulated in the photoelectric transducer PD are transferred to the floating de-fusion FD, and the normal light intensity signal is outputted to the column direction common signal line L14.

Here, a difference between the previously set initialization potential and the potential of the sampling capacitor C31 and the clamp capacitor C32 is detected.

After the row selection pulse SELECT is turned OFF at time t12 to turn the MOS transistor Q14 OFF, then from time t13 to time t14, one horizontal scanning is performed for signal lines in every column. Here, a signal component is obtained by detecting all high light intensity signals.

Accordingly, it is possible to perform two horizontal transfers for transferring the high light intensity signal component and the normal light intensity signal component separately and at a high speed.

Note that, by the pulse generating circuit 50c, at time t15, the reset pulse RS, the row selection pulse SELECT, the sample hold pulse SHNC, and the capacitor initialization pulse CLNC are turned ON to turn the MOS transistors Q12, Q14, Q21, and Q31 ON in the pixel unit 10 in the Nth row, then as shown in (d) of FIG. 16, the floating de-fusion FD is reset by VDD, and the initialization potential of the floating de-fusion FD is outputted to the column direction common signal line L14 via the MOS transistors Q13 and Q14, thereby generating an initialization voltage for detecting high light intensity signal in the photoelectric transducer PD in the pixel unit 10 in the N+1st row.

Then, by the pulse generating circuit 50c, after the reset pulse RS and the capacitor initialization pulse CLNC are turned OFF to turn the MOS transistors Q12 and Q31 OFF in the pixel unit 10 in the Nth row at time t16, then at time t17, the row selection pulse SELECT is turned OFF to turn the MOS transistor Q14 OFF in the pixel unit 10 in the Nth row, after that, during one frame period from time t18 to time 119, the reset pulse RS is turned ON to temporarily set the floating de-fusion FD with an initialization potential, and then during one frame period the transfer pulse TRANS is turned ON for multiple times by a voltage lower than a normal pulse, so that, as shown in (e) of FIG. 16, electric charges which have passed through the gate potential of the MOS transistor Q11 for transferring electric charges are accumulated in the floating de-fusion FD.

The transfer pulse TRAN gradually shortens a interval between the ON states, for example, from a period A to a period B. In a case where incident light has intensity whose proportional electric charge amount is slightly larger than a normal saturated electric charge amount, the electric charges are accumulated in the floating de-fusion FD during a long accumulation period such as the period A. On the other hand, in a case where incident light has intensity whose proportional electric charge amount is much larger than the normal saturated electric charge amount, the electric charges are accumulated in the floating de-fusion FD also during a short accumulation period such as a period G. As a result, by the transfer pulse TRAN during all periods A to G, the electric charges are added into the floating de-fusion FD.

Thus, by setting more accumulation periods which are gradually shortened during one frame period, for example, from the period A to the period G, it is possible to achieve a wider dynamic range when incident light has high intensity.

Thereby the accumulation signals proportional to high intensity light which are accumulated in the floating de-fusion FD are transferred from time t6 to time t7, and the accumulation signals proportional to normal intensity light which have not passed through the gate potential of the MOS transistor Q11 for transferring electric charges are transferred from time t13 to time t14. By adding those two signal components together in the signal processing unit 60 in a later stage, it is possible to obtain the output characteristics as shown in FIGS. 6 and 7.

Moreover, in a case where the accumulation signal proportional to normal intensity light is not more than a predetermined amount in the signal processing unit 60, by setting the accumulation signal proportional to high intensity light not to be added, thereby eliminating a component of the accumulation signal proportional to high intensity light which contains a dark current component that results from longtime exposure and is noticeable when incident light has low intensity, in order to output only the accumulation signal proportional to normal intensity light, so that it is possible to achieve the wider dynamic range with little dark currents.

### Sixth Embodiment

Next, a description is given for an operation in a case where the electric charges proportional to high intensity light and the electric charges proportional to normal intensity light are outputted separately from the floating de-fusion FD to the column direction common signal line L14.

FIG. 17 is a time chart showing timings in operation of the solid-state imaging device 3 according to the sixth embodiment of the present invention.

Timings in FIG. 17 differ from the timings in FIG. 15 in that an accumulation signal proportional to high light intensity which is more than saturated light intensity and an accumulation signal proportional to normal light intensity which is less than saturated light intensity are detected separately during one horizontal blanking period, and outputted to the horizontal signal line, so that the operation is hardly affected by dark currents.

Next, an operation of the solid-state imaging device according to the present invention is described.

Here, (a) to (c) in FIG. 17 show a reset pulse RS, a transfer pulse TRAN, and a row selection pulse SELECT, respectively, which are outputted from the pulse generating circuit 50c to the pixel unit 10 in the Nth row. (d) in FIG. 17 shows a sample hold pulse SHNC which is outputted from the pulse generating circuit 50c to the MOS transistor Q21. (e) in FIG. 17 shows a capacitor initialization pulse CLNC which is outputted from the pulse generating circuit 50c to the MOS transistor Q31. (f) in FIG. 17 shows a horizontal selection pulse HSR which is outputted from the pulse generating circuit 50c to the MOS transistor Q41.

The pulse generating circuit 50c turns all pulses OFF at time t0. At time t1, the reset pulse RS, the row selection pulse SELECT for the pixel unit 10 in the Nth row are turned ON and also the sample hold pulse SHNC and the capacitor initialization pulse CLNC are turned ON, and then at time t2, the reset pulse RS and the capacitor initialization pulse CLNC are turned OFF, so that an initialization potential of the floating de-fusion FD in the pixel unit 10 of the Nth is outputted to the column direction common signal line L14 via the MOS transistors Q13 and Q14. Here, potentials of the sampling capacitor C31 and the clamp capacitor C32 are detected and replaced with an initialization potential. Next, from time t3 to time t4, the transfer pulse TRAN for the pixel unit 10 in the Nth row is turned ON, and the normal light intensity signal whose proportional light intensity is less than saturated light intensity is outputted to the column direction common signal line L14 via the MOS transistors Q13 and Q14. Here, a difference between the previously set initialization potential and the potential of the sampling capacitor C31 and the clamp capacitor C32 is detected. Then, after the row selection pulse SELECT and the sample hold pulse SHNC are turned OFF at time t5, then from time t6 to time t7, one horizontal scanning is performed for signal lines in every column. Here, a signal component is obtained by detecting all normal light intensity signals.

Next, at time t8, the reset pulse RS and the row selection pulse SELECT for the pixel unit 10 in the Nth row are turned ON and also the sample hold pulse SHNC and the capacitor initialization pulse CLNC are turned ON, and at time t9, the reset pulse RS, the row selection pulse SELECT, and the capacitor initialization pulse CLNC are turned OFF, so that an initialization potential of the floating de-fusion FD in the pixel unit 10 of the Nth row is outputted to the column direction common signal line L14 via the MOS transistors Q13 and Q14. Here, potentials of the sampling capacitor C31 and the clamp capacitor C32 are detected and replaced with an initialization potential.

After that, from time t9 to time t10, the transfer pulse TRAN is turned ON for multiple times by a voltage lower than a normal pulse, so that electric charges which have passed through the gate potential of the MOS transistor Q11 are accumulated in the floating de-fusion FD. The transfer pulse TRAN gradually shortens a interval between the ON states, for example, from a period A to a period B. In a case where incident light has intensity whose proportional electric charge amount is slightly larger than a normal saturated electric charge amount, the electric charges are accumulated in the floating de-fusion FD during a long accumulation period such as the period A. On the other hand, in a case where incident light has intensity whose proportional electric charge amount is much larger than the normal saturated electric charge amount, the electric charges are accumulated in the floating de-fusion FD also during a short accumulation period such as a period G. As a result, by the transfer pulse TRAN during all periods A to G, the electric charges are added into the floating de-fusion FD. Thus, by setting more accumulation periods which are gradually shortened during one frame period, for example, from the period A to the period G, it is possible to achieve a wider dynamic range when incident light has high intensity. By the high intensity light accumulation signal, whose proportional light intensity is more than the saturated light intensity, accumulated in the floating de-fusion FD, from time t10 to time 11, the row selection pulse SELECT is set to ON, so that electric charges are accumulated in the floating de-fusion FD and outputted to the column direction common signal line L14 via the MOS transistors Q13 and Q14. Here, a difference between the previously set initialization potential and the potential of the sampling capacitor C31 and the clamp capacitor C32 is detected. From time t12 to time t13, one horizontal scanning is performed for signal lines in every column. Here, a signal component is obtained by detecting all high light intensity signals. By adding those two signal components together by the signal processing circuit in a later stage, it is possible to obtain output characteristics as shown in FIGS. 6 and 7. Moreover, in a case where the accumulation signal proportional to normal intensity light is not more than a predetermined amount in the signal processing unit 60, by setting the accumulation signal proportional to high intensity light not to be added, thereby eliminating a component of the accumulation signal proportional to high intensity light which contains a dark current component that results from longtime exposure and is noticeable when incident light has low intensity, in order to output only the accumulation signal proportional to normal intensity light, so that it is possible to achieve the wider dynamic range with little dark currents.

Note that the sixth embodiment has described that the sample hold pulse SHNC is set to high level from time t8 to time t11, but the sample hold pulse SHNC may become high level in synchronization with the row selection pulse SELECT.

### Seventh Embodiment

The solid-state imaging device according to the present invention is described with reference to FIGS. 12 and 18.

FIG. 18 is a time chart showing timings in operation of a solid-state imaging device according to the seventh embodiment of the present invention.

Here, in the above first to sixth embodiments has a structure having the following two operation modes: a whole transfer for transferring almost all of the electric charges accumulated in the photoelectric transducer PD to the floating de-fusion FD and a partial transfer for transferring only a part of the accumulation electric charges that exceeds a predetermined amount to the floating de-fusion FD. On the other hand, the solid-state imaging device operated at the timings of FIG. 18 has a structure having the following two operation modes: a whole reset for setting the floating de-fusion FD with an initial voltage, and a partial reset for setting the floating de-fusion FD with a predetermined voltage which is different from the initial voltage.

Here, (a) to (c) in FIG. 18 show a reset pulse RS, a transfer pulse TRAN, and a row selection pulse SELECT, respectively, which are outputted from the pulse generating circuit 50c to the pixel unit 10 in the Nth row. (d) in FIG. 18 shows a sample hold pulse SHNC which is outputted from the pulse generating circuit 50c to the MOS transistor Q21. (e) in FIG. 18 shows a capacitor initialization pulse CLNC which is outputted from the pulse generating circuit 50c to the MOS transistor Q31. (f) in FIG. 18 shows a horizontal selection pulse HSR which is outputted from the pulse generating circuit 50c to the MOS transistor Q41.

Timings in FIG. 18 differ from the timings in FIG. 13 in that electric charges which are leaked out from the photoelectric transducer PD into the floating de-fusion FD are used as the high intensity light accumulation signal, and therefore, during one frame period prior to an readout operation period for the pixel unit 10 in the Nth row, the accumulated charges are controlled by the reset pulse RS.

Next, an operation of the solid-state imaging device according to the present invention is described. The all pulses are turned OFF at time t0 which is one frame period prior to the readout operation period for the pixel unit 10 in the Nth row. From time t1 to time t2, the reset pulse RS is turned ON, and after that, an interval between the ON-states is gradually shortened, for example, from a period A to a period B, thereby gradually lowering a voltage supplied by the reset pulse RS, so that accumulated amount of the electric charges which are leaked out from the photoelectric transducer PD to the floating de-fusion FD is controlled. Note that resetting floating de-fusion FD by gradually lowering the voltage supplied by the reset pulse RS is referred to as a partial reset or an incomplete reset. In a case where incident light has intensity slightly larger than a normal saturated electric charge amount, the electric charges are accumulated in the floating de-fusion FD during a long accumulation period such as the period A, and in a case where incident light has intensity much larger than the normal saturated electric charge amount, the electric charges are added in the floating de-fusion FD even during a short accumulation period such as a period G, so that by the transfer pulse TRAN during all periods from A to G the electric charges are accumulated in the floating de-fusion FD.

Thus, by setting more accumulation periods which are gradually shortened, for example, from a period A to a period F during one frame period, it is possible to achieve a wider dynamic range when incident light has high intensity. When the transfer pulse TRAN, the row selection pulse SELECT, and the sample hold pulse SHNC are turned ON at time t3, the electric charges proportional to high intensity light which are accumulated in the floating de-fusion FD during one frame period are added to the electric charges proportional to normal intensity light which are accumulated in the photoelectric transducer PD during one frame period, and potentials of the total electric charges are outputted to the column direction common signal line L14 via the MOS transistors Q13 and Q14.

After the transfer pulse TRAN is turned OFF at time t4, then from time t5 to time t6, the reset pulse RS and the capacitor initialization pulse CLNC are turned ON, and an initialization potential of the floating de-fusion FD is outputted from the column direction common signal line L14 via the MOS transistors Q13 and Q14. Note that resetting the floating de-fusion FD by the reset pulse RS with a high voltage is referred to as a whole reset or a complete reset. Here, the electric charges are re-distributed into the sampling capacitor C31 and the clamp capacitor C32, and a voltage in which a threshold difference of the MOS transistor Q13 is eliminated from the re-distributed electric charges is obtained. After the row selection pulse SELECT and the sample hold pulse SHNC are turned OFF at time t7, then from time t8 to time t9, one horizontal scanning is performed for signal lines in every column and the one horizontal period ends. Thus, by setting more accumulation periods which are gradually shortened from the period A to the period G during one frame period, it is possible to achieve a wider dynamic range when incident light has high intensity. By adding, for multiple times in signal detection processing from time t1 to time t5, the high light intensity accumulation signal, whose proportional light intensity is more than the saturated light intensity, accumulated in the floating de-fusion FD with the normal light intensity amount signal, whose proportional light intensity is less than the saturated light intensity, which have not passed through the gate potential of the MOS transistor Q11, it is possible to obtain output characteristics as shown in FIGS. 6 and 7.

Note that the seventh embodiment has described that the voltage of the reset pulse RS is gradually lowered from time t1 to time t3, but the voltage of the reset pulse RS may be a fixed voltage as described in the fourth and the fifth embodiments.

### Eighth Embodiment

The solid-state imaging device according to the present invention is described with reference to FIGS. 12 and 19.

FIG. 19 is a time chart showing timings in operation of a solid-state imaging device according to the eighth embodiment of the present invention.

Timings in FIG. 19 differ from the timings in FIG. 13 in that the high-intensity light accumulation signal whose light intensity is more than the saturated light intensity is detected by the reset pulse RS. Next, an operation of the solid-state imaging device according to the present invention is described.

Here, (a) to (c) in FIG. 19 show a reset pulse RS, a transfer pulse TRAN, and a row selection pulse SELECT, respectively, which are outputted from the pulse generating circuit 50c to the pixel unit 10 in the Nth row. Here, (d) to (f) in FIG. 19 show a reset pulse RS, a transfer pulse TRAN, and a row selection pulse SELECT, respectively, which are outputted from the pulse generating circuit 50c to the pixel unit 10 in the N+1st row. (g) in FIG. 19 shows a sample hold pulse SHNC which is outputted from the pulse generating circuit 50c to the MOS transistor Q21. (h) in FIG. 19 shows a capacitor initialization pulse CLNC which is outputted from the pulse generating circuit 50c to the MOS transistor Q31. (i) in FIG. 19 shows a horizontal selection pulse HSR which is sequentially outputted from the pulse generating circuit 50c to the MOS transistor Q41 on each column.

The pulse generating circuit 50c turns all pulses OFF at time t0. From time t1 to time t2, the reset pulse RS for the pixel unit 10 in the N+1st row is turned ON, and after that, an interval between the ON-states is gradually shortened, for example, from a period A to a period B and a voltage supplied by the reset pulse RS is gradually lowered, so that the accumulated amount of the electric charges which are leaked out from the photoelectric transducer PD to the floating de-fusion FD can be controlled. In a case where incident light has intensity slightly larger than a normal saturated electric charge amount, the electric charges are accumulated in the floating de-fusion FD during a long accumulation period such as the period A, and in a case where incident light has intensity much larger than the normal saturated electric charge amount, the electric charges are accumulated in the floating de-fusion FD even during a short accumulation period such as a period G, so that by the transfer pulse TRAN during all periods from A to G the electric charges are added in the floating de-fusion FD. Thus, by setting more accumulation periods which are gradually shortened from the period A to the period G during one frame period, it is possible to achieve a wider dynamic range when incident light has high intensity.

After, at time t3, the reset pulse RS, the row selection pulse SELECT, the sample hold pulse SHNC, and the capacitor initialization pulse CLNC for the pixel unit 10 in a previously scanned row, namely the Nth row, are turned ON, then a signal proportional to the accumulated electric charges is outputted to the column direction common signal line L14 via the MOS transistors Q13 and Q14, and an initialization potential of the floating de-fusion FD is set, then at time t4, the reset pulse RS, the row selection pulse SELECT, and the capacitor initialization pulse CLNC for the previously scanned row are turned OFF. From time t5 to time t6, the row selection pulse SELECT is set to ON, high intensity light, whose light intensity is more than the saturated light intensity, accumulation signals accumulated in the floating de-fusion FD are outputted to the column direction common signal line L14 via the MOS transistors Q13 and Q14, and the electric charges are re-distributed into the sampling capacitor C31 and the clamp capacitor C32, and a voltage in which a threshold difference of the MOS transistor Q13 is eliminated from the re-distributed electric charges is obtained. From time t7 to time t8, one horizontal scanning is performed for signal lines in every column, assuming the above signals as the high light intensity signals.

Next, at time t8, the reset pulse RS, the row selection pulse SELECT, the sample hold pulse SHNC, and the capacitor initialization pulse CLNC for the pixel unit 10 in the N+1st row are turned ON, and at time t9, the reset pulse RS and the capacitor initialization pulse CLNC are turned OFF. Thereby a signal proportional to the accumulated electric charges is outputted to the column direction common signal line L14 via the MOS transistors Q13 and Q14, and an initialization potential of the floating de-fusion FD is set. Next, from time t10 to time t11, the transfer pulse TRAN is set to ON, then at time t12, the row selection pulse SELECT and the sample hold pulse SHNC are turned OFF, and the normal light intensity signals, whose light intensity is less than the saturation light intensity, which have not passed through the gate potential of the MOS transistor Q11 are outputted into the column direction common signal line L14 via the MOS transistors Q13 and Q14. Here, the electric charges are re-distributed into the sampling capacitor C31 and the clamp capacitor C32, and a voltage in which a threshold difference of the MOS transistor Q13 is eliminated from the re-distributed electric charges is obtained. From time t13 to time t14, one horizontal scanning is performed for signal lines in every column, assuming the above signals as the normal light intensity signals.

Accordingly, it is possible to separately detect transfer of the high light intensity signal whose proportional light intensity is more than the saturated light intensity and transfer of the normal light intensity signal whose proportional light intensity is less than the saturated light intensity, and also to perform horizontal transfers separately and at a high speed. Thus, by setting more accumulation periods which are gradually shortened, for example, from the period A to the period G during one frame period, it is possible to achieve a wider dynamic range when incident light has high intensity. By adding those two signal components by the signal processing unit 60 in a later stage, it is possible to obtain output characteristics as shown in FIGS. 6 and 7. Moreover, in a case where the accumulation signal proportional to normal intensity light is not more than a predetermined amount, by setting the accumulation signal proportional to high intensity light not to be added, thereby eliminating a component of the accumulation signal proportional to high intensity light which contains a dark current component that results from longtime exposure and is noticeable when incident light has low intensity, in order to output only the accumulation signal proportional to normal intensity light, so that it is possible to achieve the wider dynamic range with little dark currents.

Note that the eighth embodiment has described that the voltage of the reset pulse RS is gradually lowered from time t1 to time t3, but the voltage of the reset pulse RS may be gradually increased or may be a fixed voltage as described in the fourth and the fifth embodiments.

### Ninth Embodiment

Next, a solid-state imaging device according to the ninth embodiment of the present invention is described.

FIG. 20 is a circuit diagram showing a structure of a solid-state imaging device according to the ninth embodiment of the present invention. Note that a plurality of pixel units are actually arranged in rows and columns, but FIG. 20 shows one of the pixel units. Note that the reference numerals for the solid-state imaging device 3 in FIG. 12 are assigned to identical elements in FIG. 20 so that the details of those elements are same as described above.

The ninth embodiment differs from the fifth embodiment in that a signal proportional to high intensity light and a signal proportional to normal intensity light are separately detected by noise signal cancel units 30a and 30b which are formed in a solid-state imaging device 4, and a built-in addition control unit 70 (comparator 71) determines whether or not the signal proportional to high intensity light should be added to the signal proportional to normal intensity light.

As shown in FIG. 20, the solid-state imaging device 4 is comprised of a pixel unit 10, MOS transistors Q21a and Q21b, noise signal cancel units 30a and 30b, an addition control unit 70, MOS transistors Q41a and Q41b, a signal processing unit 60, a power line L10, a reset pulse supply signal line L11, a transfer pulse supply signal line L12, a row selection pulse supply signal line L13, a column direction common signal line L14, sample hold pulse supply signal lines L15a and L15b, capacitor initialization pulse supply signal lines L16a and L16b, a capacitor initialization bias supply line L17, a horizontal selection pulse supply signal line L18, a horizontal output signal line L19, and the like.

The noise signal cancel unit 30a is, like the noise signal cancel unit 30, comprised of a MOS transistor Q31a, a sampling capacitor C31a, and a clamp capacitor C32a. Furthermore, the noise signal cancel unit 30b is, like the noise signal cancel unit 30, composed of a MOS transistor Q31b, a sampling capacitor C31b, and a clamp capacitor C32b.

The addition control unit 70 is comprised of a comparator 71, an inverter 72, and MOS transistors Q71, Q72, Q73, Q74, and Q75.

The column direction common signal line L14 is connected to both a drain of the MOS transistor Q21a and a drain of the MOS transistor Q21b. Regarding the MOS transistor Q21a, a gate is connected to the sample hold pulse supply signal line L15a, and a source is connected to one terminal of the sampling capacitor C31a in the noise signal cancel unit 30a. Regarding the MOS transistor Q21b, a gate is connected to the sample hold pulse supply signal line L15b, and a source is connected to one terminal of the sampling capacitor C31b in the noise signal cancel unit 30b.

Regarding the MOS transistor Q31a in the noise signal cancel unit 30a, a drain is connected to the capacitor initialization bias supply line L17, a source is connected to the sampling capacitor C31a, the clamp capacitor C32a, and a drain of MOS transistor Q41a, and a gate is connected to the capacitor initialization pulse supply signal line L16a. Regarding the MOS transistor Q31b in the noise signal cancel unit 30b, a drain is connected to the capacitor initialization bias supply line L17, a source is connected to the sampling capacitor C31b, the clamp capacitor C32b, and a drain of the MOS transistor Q41b, and a gate is connected to the capacitor initialization pulse supply signal line L16b.

The comparator 71 in the addition control unit 70 compares a voltage of the clamp capacitor C32a with a predetermined reference voltage VREF, and in a case where the voltage of the clamp capacitor C32a is higher than the reference voltage VREF, a high-level signal is outputted, and in a case where the voltage of the clamp capacitor C32a is lower than the reference voltage VREF, a low-level signal is outputted. The inverter 72 reverse the level of the signal outputted from the comparator 71.

Regarding the MOS transistor Q71, a gate is connected to the output of comparator 71, a drain is connected to a source of the MOS transistor Q31a, and a source is connected to a source of the MOS transistor Q72 and a drain of the MOS transistor Q73. Regarding the MOS transistor Q72, a gate is connected to the output of comparator 71, a drain is connected to the clamp capacitor C32b. Regarding the MOS transistor Q73, a gate is connected to the output of inverter 72, a source is connected to ground GND. Regarding the MOS transistor Q74, a gate is connected to the output of inverter 72, a drain is connected to the horizontal selection pulse supply signal line L18, a source is connected to a gate of the MOS transistor Q41a. Regarding the MOS transistor Q75, a gate is connected to an output of the comparator 71, a drain is connected to the horizontal selection pulse supply signal line L18, and a source is connected to a gate of the MOS transistor Q41b.

Regarding the MOS transistor Q41a, a drain is connected to the sampling capacitor C31a and the clamp capacitor C32a, and a source is connected to the horizontal output signal line L19. Regarding the MOS transistor Q41b, a drain is connected to the sampling capacitor C31b and the clamp capacitor C32b, and a source is connected to the horizontal output signal line L19.

The pulse generating circuit 50d outputs a reset pulse RS to the reset pulse supply signal line L11, a transfer pulse TRAN to the transfer pulse supply signal line L12, and a row selection pulse SELECT to the row selection pulse supply signal line L13.

Furthermore, the pulse generating circuit 50d outputs a sample hold pulse SHNC1 to the sample hold pulse supply signal line L15b, and a capacitor initialization pulse CLNC1 to the capacitor initialization pulse supply signal line L16b. Still further, the pulse generating circuit 50d outputs a sample hold pulse SHNC2 to the sample hold pulse supply signal line L15a, and a capacitor initialization pulse CLNC2 to the capacitor initialization pulse supply signal line L16a. Still further, the pulse generating circuit 50d outputs a horizontal selection pulse HSR to the horizontal selection pulse supply signal line L18.

Thereby, based on a determination result by the comparator 71 in the addition control unit 70, the signal proportional to normal intensity light or a signal obtained by adding the signal proportional to high intensity light to the signal proportional to normal intensity light is outputted to the horizontal output signal line L19.

Next, an operation of a solid-state imaging device 4 according to the present invention is described.

FIG. 21 is a time chart showing timings in operation of the solid-state imaging device 4 according to the ninth embodiment of the present invention.

Here, (a) to (c) in FIG. 21 show a reset pulse RS, a transfer pulse TRAN, and a row selection pulse SELECT, respectively, which are outputted from the pulse generating circuit 50d to the pixel unit 10 in the N−1st row. (d) to (f) in FIG. 21 show a reset pulse RS, a transfer pulse TRAN, and a row selection pulse SELECT, respectively, which are outputted from the pulse generating circuit 50d to the pixel unit 10 in the Nth row. (g) in FIG. 21 shows a sample hold pulse SHNC1 which is outputted from the pulse generating circuit 50d to the MOS transistor Q21b. (h) in FIG. 21 shows a capacitor initialization pulse CLNC1 which is outputted from the pulse generating circuit 50d to the MOS transistor Q31b. (i) in FIG. 21 shows a sample hold pulse SHNC2 which is outputted from the pulse generating circuit 50d to the MOS transistor Q21a. (j) in FIG. 21 shows a capacitor initialization pulse CLNC2 which is outputted from the pulse generating circuit 50d to the MOS transistor Q31a. (k) in FIG. 21 shows a horizontal selection pulse HSR which is sequentially outputted from the pulse generating circuit 50d to the MOS transistors Q41a and Q41b on each column.

The pulse generating circuit 50d turns all pulses OFF at time t0.

By the pulse generating circuit 50d, at time t1, the reset pulse RS, the row selection pulse SELECT for the pixel unit 10 in the N−1st row are turned ON and also the sample hold pulse SHNC1 and the capacitor initialization pulse CLNC1 are turned ON, then at time t2, the reset pulse RS and the capacitor initialization pulse CLNC1 for the pixel unit 10 in the N−1st row are turned OFF, and after that, an initialization potential of the floating de-fusion FD in the pixel unit 10 of the N−1st row is outputted to the column direction common signal line L14 via the MOS transistors Q13 and Q14 in the pixel unit 10 of the N−1st row.

Here, potentials in the sampling capacitor C31 and the clamp capacitor C32 are detected and replaced with the initialization potential.

By the pulse generating circuit 50d, after the row selection pulse SELECT for the pixel unit 10 in the N−1st row is turned ON at time t3, then from time t4 to time t5, the row selection pulse SELECT for the pixel unit 10 in the Nth row is se to ON, and a high light intensity signal is outputted to the column direction common signal line L14 via the MOS transistors Q13 and Q14.

Here, a difference between the previously set initialization potential and the potential of the sampling capacitor C31 and the clamp capacitor C32 is detected.

By the pulse generating circuit 50d, at time t6, in order not to input the signal passing the column direction common signal line L14 into the noise signal cancel unit 30b, the sample hold pulse SHNC1 is turned OFF to turn the MOS transistor Q21b OFF.

By the pulse generating circuit 50d, at time t7, the reset pulse RS and the row selection pulse SELECT for the pixel unit 10 in the Nth row are turned ON and also the sample hold pulse SHNC2 and the capacitor initialization pulse CLNC2 are turned ON, then at time t8, the reset pulse RS for the pixel unit 10 in the Nth row is turned OFF and also the capacitor initialization pulse CLNC2 is turned OFF, and after that, an initialization potential of the floating de-fusion FD in the pixel unit 10 of the Nth row is outputted to the column direction common signal line L14 via the MOS transistors Q13 and Q14.

Here, potentials of the sampling capacitor C31 and the clamp capacitor C32 are detected and replaced with an initialization potential.

By the pulse generating circuit 50d, from time 9 to time t10, the transfer pulse TRAN for the pixel unit 10 in the Nth row is turned ON, and the normal light intensity signal is outputted to the column direction common signal line L14 via the MOS transistors Q13 and Q14.

Here, a difference between the previously set initialization potential and the potential of the sampling capacitor C31 and the clamp capacitor C32 is detected. Here, the comparator 71 compares a difference voltage with a reference voltage VREF, and in a case where the difference voltage is higher than a certain level voltage (a saturation voltage in this case), the comparator 71 outputs a high-level voltage. Thereby, the MOS transistors Q71, Q72, and Q75 become ON state, and the MOS transistors Q73 and Q74 become OFF state, so that a voltage of the clamp capacitor C32a is added with a voltage of the clamp capacitor C32b.

Furthermore, by the pulse generating circuit 50d, after the row selection pulse SELECT and the sample hold pulse SHNC2 are turned OFF at time t11, then from time t12 to time t13, one horizontal scanning is performed for signal lines in every column. Here, the horizontal selection pulse HSR is applied only to the MOS transistor Q41b, so that signal components to be transferred horizontally are obtained by adding a component of the normal light intensity signal with a component of all of the high light intensity signals.

On the other hand, by the pulse generating circuit 50d, from time t9 to time t10, the transfer pulse TRAN is turned ON and the normal light intensity signal is outputted to the column direction common signal line L14 via the MOS transistors Q13 and Q14, and when the difference between the predetermined initialization potential and the potentials of the sampling capacitor C31 and the clamp capacitor C32 is detected, the comparator 71 compares the difference voltage with the reference voltage VREF, and in a case where the difference voltage is lower than a certain level voltage (a saturation voltage in this case), the comparator 71 outputs a low-level voltage.

Thereby the MOS transistors Q71, Q72, and Q75 become OFF state, and the MOS transistors Q73 and Q74 become ON state, so that only voltage of the clamp capacitor C32a performs one horizontal scanning for signal lines in every column from time t12 to time t13.

As described above, the comparator 71 in the addition control unit 70 can determined whether incident light has high intensity or normal intensity in the solid-state imaging device 4, thereby eliminating a component of the accumulation signal proportional to high intensity light which contains a dark current component that results from longtime exposure and is noticeable when incident light has low intensity, in order to output only the accumulation signal proportional to normal intensity light, so that it is possible to achieve the wider dynamic range with little dark currents.

Note that, by the pulse generating circuit 50d, at time t14, the reset pulse RS and the row selection pulse SELECT are turned ON and also the capacitor initialization pulse CLNC1 is turned ON, and the initialization potential of the floating de-fusion FD is outputted to the column direction common signal line L14 via the MOS transistors Q13 and Q14, thereby generating an initialization voltage for detecting high light intensity signal in the photoelectric transducer PD in the pixel unit 10 in the Nth row.

After the reset pulse RS and the capacitor initialization pulse CLNC1 are turned OFF at time t15, then at time 16 the row selection pulse SELECT is turned OFF, and after that the transfer pulse TRAN is turned ON for multiple times during one frame period by a voltage lower than the normal pulse, so that the electric charges which have passed through the gate potential of the MOS transistor Q11 are accumulated in the floating de-fusion FD. The transfer pulse TRAN gradually shortens a interval between the ON states, for example, from a period A to a period B. In a case where incident light has intensity whose proportional electric charge amount is slightly larger than a normal saturated electric charge amount, the electric charges are accumulated in the floating de-fusion FD during a long accumulation period such as the period A. On the other hand, in a case where incident light has intensity whose proportional electric charge amount is much larger than the normal saturated electric charge amount, the electric charges are accumulated in the floating de-fusion FD also during a short accumulation period such as a period G. As a result, by the transfer pulse TRAN during all periods A to G, the electric charges are added into the floating de-fusion FD. Thus, by setting more accumulation periods which are gradually shortened during one frame period, for example, from the period A to the period G, it is possible to achieve a wider dynamic range when incident light has high intensity.

The accumulation signals proportional to high intensity light which are accumulated in the floating de-fusion FD are transferred from time t4 to time t5, and the accumulation signals proportional to normal intensity light which have not passed through the gate potential of the MOS transistor Q11 are transferred from time t9 to time t10. Those two signal components are held in separate noise cancel circuits, and in a case where those two signal components are added together based on a voltage level examination by the comparator 71, it is possible to obtain the output characteristics as shown in FIGS. 6 and 7. Moreover, it is possible to eliminate a component of the accumulation signal proportional to high intensity light which contains a dark current component that results from longtime exposure and is noticeable when incident light has low intensity, in order to output only the accumulation signal proportional to normal intensity light, so that a wider dynamic range with little dark currents can be achieved.

Note that the ninth embodiment has described the case where the MOS transistors Q11 and Q12 are controlled to be driven at the same timings as described in the fourth embodiment, but the MOS transistors Q11 and Q12 can be controlled to be driven at the same timings described in the fifth to eighth embodiments.

Note that, in the fourth to ninth embodiments, by setting that the MOS transistor Q11 as a transferring means for transferring electric charges is an enhancement-mode MOS transistor and a threshold value of the MOS transistor Q11 is lower than threshold values of other enhancement-mode MOS transistors, and the MOS transistor Q12 for setting an accumulation region for accumulating electric charges with a voltage of the power line is a depression-mode MOS transistor, it is possible to provide a solid-state imaging device which can show the characteristics more easily.

Note also that, in the fourth to ninth embodiments, by setting that all circuits are NMOS transistors and that noise cancel capacitors are depression-mode NMOS capacitors, it is possible to reduce a manufacturing cost and to provide a solid-state imaging device with little dark currents.

Moreover, it is possible to realize a camera using the above described solid-state imaging device.

### Tenth Embodiment

FIG. 22 is a diagram showing a structure of a camera using the solid-state imaging device of the above first to ninth embodiments.

As shown in FIG. 22, a camera 400 is comprised of: a lens 401 for providing an optical image of a subject on an imaging device; an optical system 402, such as a mirror and a shutter for perform optical processing for the optical image which has passed through the lens 401; a MOS imaging device 403 which is realized by the above described solid-state imaging device; a signal processing unit 410; a timing control unit 411; and the like. The timing control unit 411 is comprised of: a CDS circuit 404 for obtaining a difference between the output signal and a field through signal which is outputted from the MOS image device 403; an OB clamp circuit 405 for detecting an OB level signal which is outputted from the CDS circuit 404; a GCA 406 for obtaining a difference between the OB level and signal level of an effective pixel and adjusting a gain of the difference; an ADC 407 for converting an analog signal outputted from the GCA 406 to a digital signal; and the like. The timing control unit 411 is comprised of: a DSP 408 for performing signal processing for the digital signal outputted from the ADC 407, and controlling timings of driving; a TG 409 for generating, at various timings, various kinds of drive pulses for the MOS imaging device 403 based on instructions from the DSP 408; and the like.

According to the camera 400 having the above described structure, by the MOS imaging device 403 realized by the above solid-state imaging device, it is possible to realize a camera which can provide high-resolution images by using the solid-state imaging device which can obtain an output characteristic without preventing linearity even in a high light-intensity range, and at the same time achieve a much wider dynamic range.

Although only some exemplary embodiments of the present invention have been described in detail above, those skilled in the art will be readily appreciate that many modifications are possible in the exemplary embodiments without materially departing from the novel teachings and advantages of the present invention. Accordingly, all such modifications are intended to be included within the scope of this invention.

### INDUSTRIAL APPLICABILITY

The solid-state imaging device according to the present invention can achieve less photosensitivity reduction, high linearity even when the incident light has high intensity, and an optical response of a wide dynamic range, and is suitable for a use in a digital camera used in conditions where intensity of incident light significantly varies from when images are captured indoors to outdoors.

1. A solid-state imaging device comprising:
a photo-detecting element operable to transduce incident light to electric charges and accumulate the electric charges;
an accumulation element operable to accumulate the electric charges; and
a transfer circuit operable to transfer the electric charges accumulated in said photo-detecting element to said accumulation element,
wherein said transfer circuit has two operation modes of: a whole transfer for transferring almost all of the accumulated electric charges to said accumulation element; and a partial transfer for transferring only a part of the accumulated electric charges which exceeds a predetermined amount to said accumulation element.

2. The solid-state imaging device according to claim 1,
wherein said transfer circuit is operable to perform the partial transfer for a plurality of times and each interval between the partial transfers is different.

3. The solid-state imaging device according to claim 2,
wherein the partial transfer is performed for three or more times and the intervals between the partial transfers become gradually shorter or longer.

4. The solid-state imaging device according to claim 1, further comprising
a reset circuit operable to reset said accumulation element,
wherein said reset circuit is operable to perform a reset operation before the whole transfer and before the partial transfer.

5. The solid-state imaging device according to claim 2, further comprising
a reset circuit operable to reset said accumulation element,
wherein said reset circuit is operable to perform a reset operation before the whole transfer and before each of the partial transfer which is performed for a plurality of times.

6. The solid-state imaging device according to claim 1,
wherein the accumulated electric charges transferred by the whole transfer are added with the accumulated electric charges transferred by the partial transfer, only in a case where the accumulated electric charges transferred by the partial transfer exceed a predetermined amount.

7. A solid-state imaging device comprising:
a photo-detecting element operable to transduce incident light to electric charges and accumulate the electric charges;
an accumulation element operable to accumulate the electric charges;
a transfer circuit operable to transfer the electric charges accumulated in said photo-detecting element to said accumulation element; and
a reset circuit operable to reset said accumulation element,
wherein said reset circuit has two operation modes of: a whole reset for setting said accumulation element with an initial voltage; and a partial reset for setting said accumulation element with a predetermined voltage which is different from the initial voltage.

8. The solid-state imaging device according to claim 7,
wherein said reset circuit is operable to perform for a plurality of times the partial resets each of which sets a different predetermined voltage.

9. The solid-state imaging device according to claim 8,
wherein the partial reset is performed for three or more times and intervals between the partial resets become gradually shorter or longer.

10. The solid-state imaging device according to claim 8,
wherein the partial reset is performed for three or more times and the predetermined voltages become gradually lower or higher.

11. The solid-state imaging device according to claim 7,
wherein the accumulated electric charges transferred after the whole reset are added with the accumulated electric charges transferred after the partial transfer, only in a case where the accumulated electric charges transferred after the partial transfer exceed a predetermined amount.

12. The solid-state imaging device according to claim 1,
wherein said transfer circuit includes an enhancement-mode transfer MOS transistor, and
a threshold value of said transfer MOS transistor is set to be lower than threshold values of other enhancement-mode transfer MOS transistors included in said solid-state imaging device.

13. The solid-state imaging device according to claim 1,
wherein all transistors included in a circuit are NMOS transistors, and
a capacitor included in a circuit is an NMOS capacitor.

14. A camera comprising the solid-state imaging device according to claim 1.

15. The solid-state imaging device according to claim 7,
wherein said transfer circuit includes an enhancement-mode transfer MOS transistor, and
a threshold value of said transfer MOS transistor is set to be lower than threshold values of other enhancement-mode transfer MOS transistors included in said solid-state imaging device.

16. The solid-state imaging device according to claim 7,
wherein all transistors included in a circuit are NMOS transistors, and
a capacitor included in a circuit is an NMOS capacitor.

17. A camera comprising the solid-state imaging device according to claim 7.
